(19) United States
(12) Patent Application Publication
(10) Pub. No.: US 2025/0285655 A1
(43) Pub. Date: Sep. 11, 2025

(54) SEMICONDUCTOR DEVICES

(71) Applicant: Samsung Electronics Co., Ltd., Suwon-si (KR)

(72) Inventors: Sunghoon Bae, Suwon-si (KR); Seungbo Ko, Suwon-si (KR); Euna Kim, Suwon-si (KR)

(21) Appl. No.: 18/991,808

(22) Filed: Dec. 23, 2024

(30) Foreign Application Priority Data
Mar. 8, 2024 (KR) 10-2024-0033038

(51) Int. Cl. G11C 5/06; H10B 12/00

(52) U.S. Cl. CPC G11C 5/06; H10B 12/482

(57) ABSTRACT

The semiconductor device may include an active pattern on a substrate including a cell array region and an extension region; a gate structure on the active pattern; a bit line structure on the active pattern; a lower contact plug structure on the cell array region of the substrate, the lower contact plug structure on an end portion of the active pattern; a first lower wiring extending along a boundary of the cell array region and the extension region on the extension region; a first upper wiring extending along the boundary of the cell array region and the extension region on the extension region, the first upper wiring on the first lower wiring; and a capacitor on the lower contact plug structure.

### CROSS-REFERENCE TO RELATED APPLICATION

This application claims priority under 35 U.S.C. § 119 to Korean Patent Application No. 10-2024-0033038 filed on Mar. 8, 2024 in the Korean Intellectual Property Office, the disclosure of which is hereby incorporated by reference in its entirety.

### TECHNICAL FIELD

Example embodiments of the present disclosure relate to a semiconductor device.

### DISCUSSION OF RELATED ART

In a method of manufacturing a DRAM device, upper wirings having various sizes and spacing may be formed by a single etching process, which may increase the difficulty of the etching process.

### SUMMARY

Example embodiments provide a semiconductor device having improved electrical characteristics.

According to example embodiments of the inventive concepts, there is a semiconductor device. The semiconductor device may include an active pattern on a substrate including a cell array region and an extension region; a gate structure on the active pattern, the gate structure extending in a first direction substantially parallel to an upper surface of the substrate; a bit line structure on the active pattern, the bit line structure extending in a second direction substantially parallel to the upper surface of the substrate and crossing the first direction; a lower contact plug structure on the cell array region of the substrate, the lower contact plug structure on an end portion of the active pattern; a first lower wiring extending on the extension region along a boundary of the cell array region and the extension region, the first lower wiring at least partially overlapping the lower contact plug structure in a horizontal direction substantially parallel to the upper surface of the substrate; a upper wiring extending on the extension region along the boundary of the cell array region and the extension region, the upper wiring on the first lower wiring; and a capacitor on the lower contact plug structure.

According to example embodiments of the inventive concepts, there is a semiconductor device. The semiconductor device may include an active pattern on a substrate including a cell array region and an extension region; a gate structure on the active pattern, the gate structure extending in a first direction substantially parallel to an upper surface of the substrate; a bit line structure on the active pattern, the bit line structure extending in a second direction substantially parallel to the upper surface of the substrate and crossing the first direction; a lower contact plug structure on the cell array region of the substrate, the lower contact plug structure on an end portion of the active pattern; a lower wiring extending on the extension region along a boundary of the cell array region and the extension region and including a recess formed at an upper portion thereof, the recess extending on the extension region along the boundary of the cell array region and the extension region; and a capacitor on the lower contact plug structure.

According to example embodiments of the inventive concepts, there is a semiconductor device. The semiconductor device may include an active pattern on a substrate including a cell array region and an extension region; a gate structure on the active pattern, the gate structure extending in a first direction substantially parallel to an upper surface of the substrate; a bit line structure on the active pattern, the bit line structure extending in a second direction substantially parallel to the upper surface of the substrate and crossing the first direction; a lower contact plug structure on the cell array region of the substrate, the lower contact plug structure on an end portion of the active pattern; a lower wiring extending on the extension region along a boundary of the cell array region and the extension region; an insulating interlayer covering a sidewall of the lower contact plug structure and a sidewall of the lower wiring and including a recess formed at an upper portion thereof, the recess extending on the extension region along the boundary of the cell array region and the extension region; and a capacitor on the lower contact plug structure.

In the method of manufacturing a semiconductor device, the upper wirings may be formed by a first etching process and a second etching process, and thus, difficulty of forming the upper wirings may be reduced.

### BRIEF DESCRIPTION OF THE DRAWINGS

FIGS. 1 to 59 are plan views and cross-sectional views illustrating a method of manufacturing a semiconductor device according to example embodiments.

FIGS. 60 to 64 are plan views and cross-sectional views illustrating a method of manufacturing a semiconductor device according to example embodiments.

FIGS. 65 to 71 are plan views and cross-sectional views illustrating a method of manufacturing a semiconductor device according to example embodiments.

FIGS. 72 to 76 are plan views and cross-sectional views illustrating a method of manufacturing a semiconductor device according to example embodiments.

### DETAILED DESCRIPTION

The above and other aspects and features of a decoupling capacitor structure and a method of forming the same, and a semiconductor device including the decoupling capacitor structure and a method of manufacturing the same in accordance with example embodiments will become readily understood from the detailed descriptions that follow, with reference to the accompanying drawings. It will be understood that, although the terms “first,” “second,” and/or “third” may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second or third element, component, region, layer or section without departing from the teachings of inventive concepts.

In addition, certain items may be described in the singular, but be provided in plural, as shown in various figures.

Terms such as “same,” “equal,” “planar,” “coplanar,” “parallel,” and “perpendicular,” as used herein encompass identicality or near identicality including variations that may occur resulting from conventional manufacturing processes. The term “substantially” may be used herein to emphasize this meaning, unless the context or other statements indicate otherwise.

It should be appreciated that an “air gap” may comprise a gap having air or other gases (e.g., such as those present during manufacturing) or may comprise a gap forming a vacuum therein.

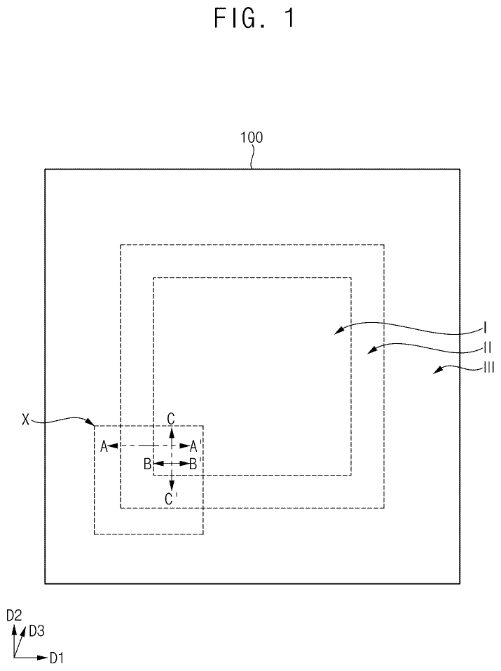

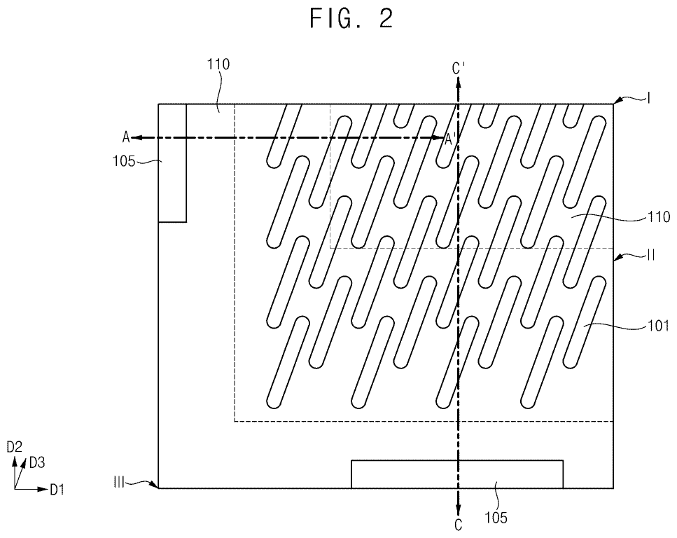

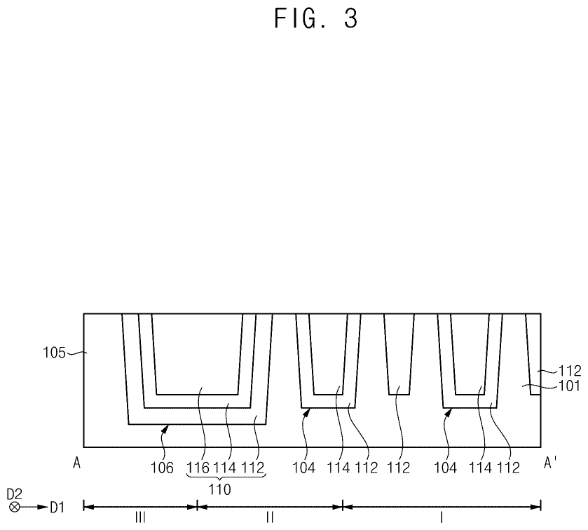

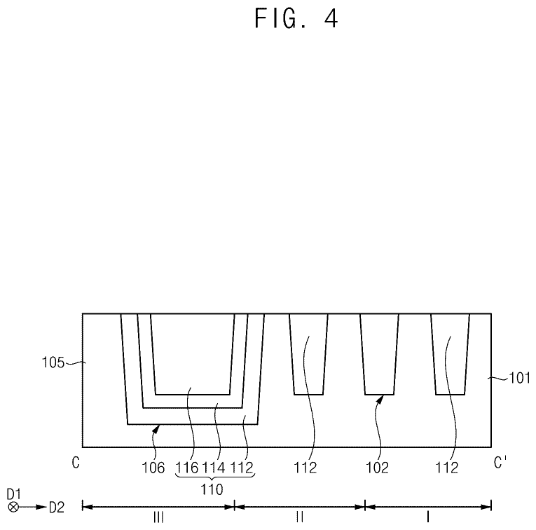

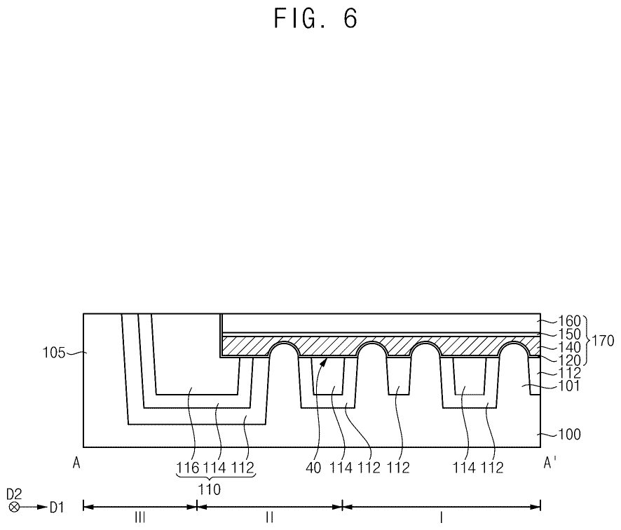

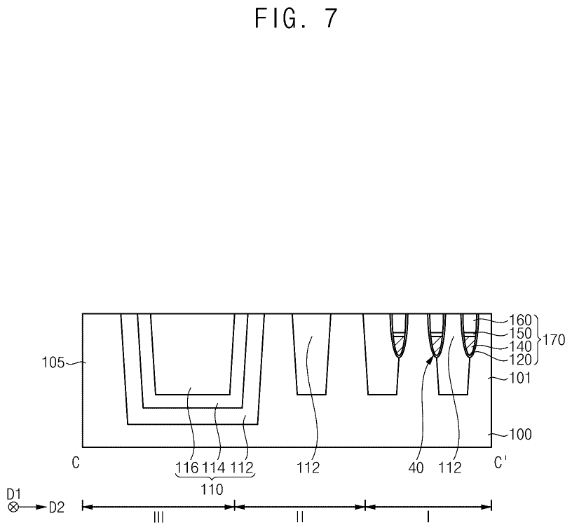

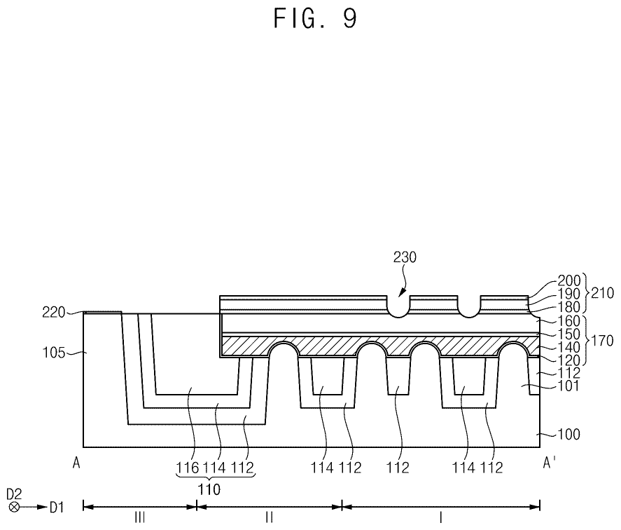

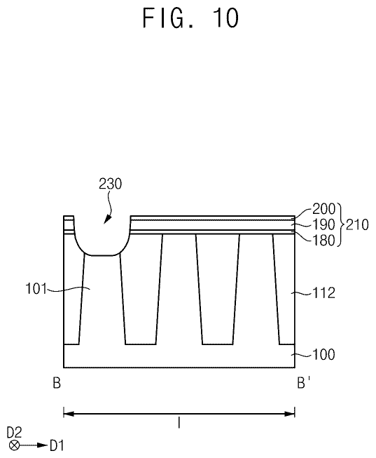

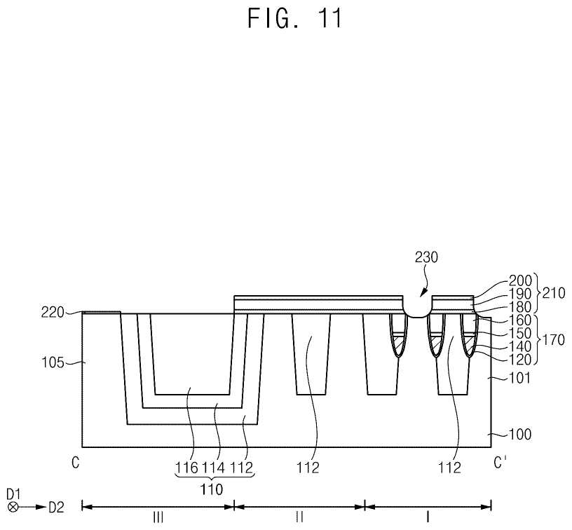

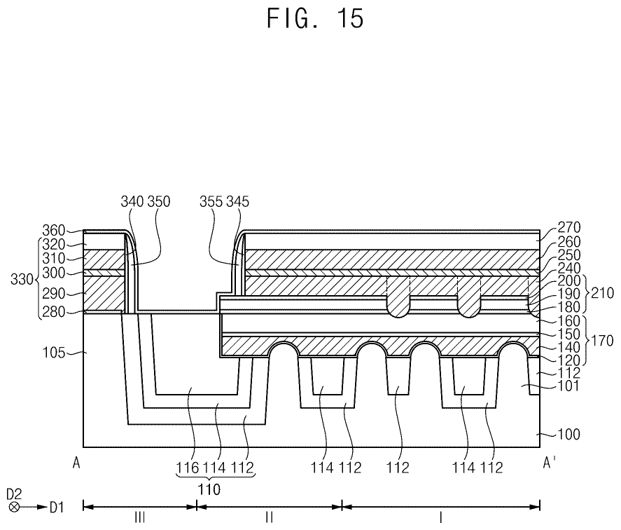

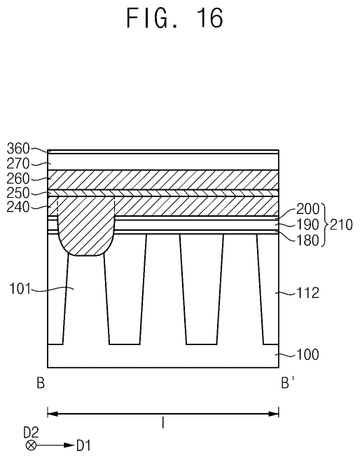

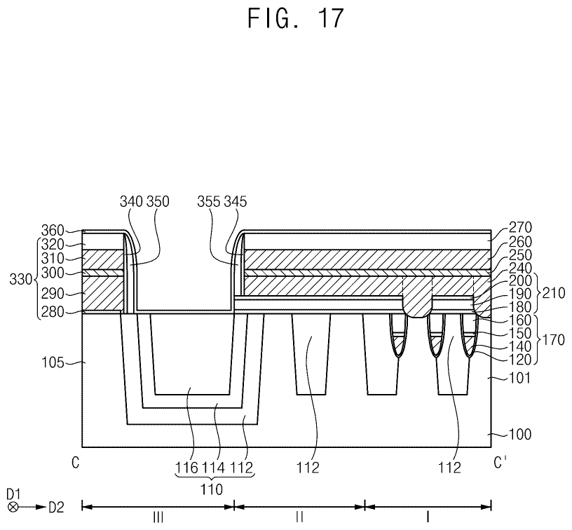

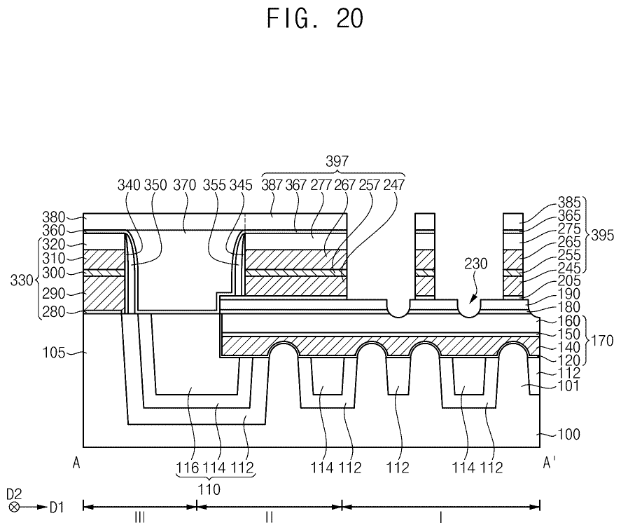

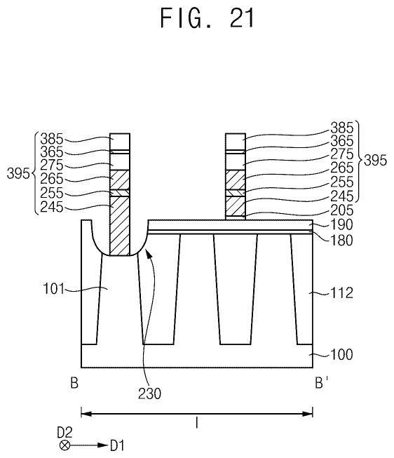

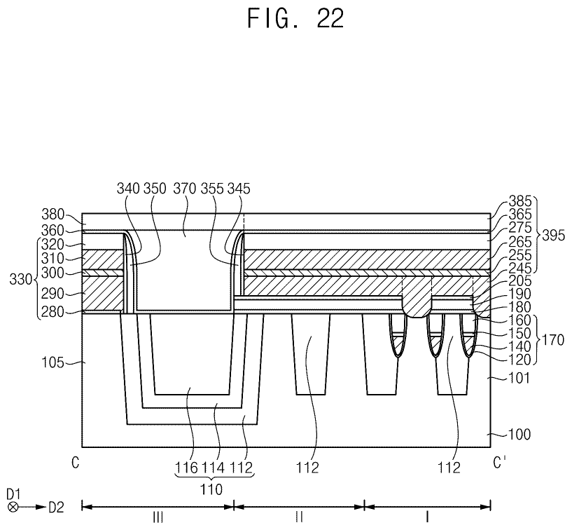

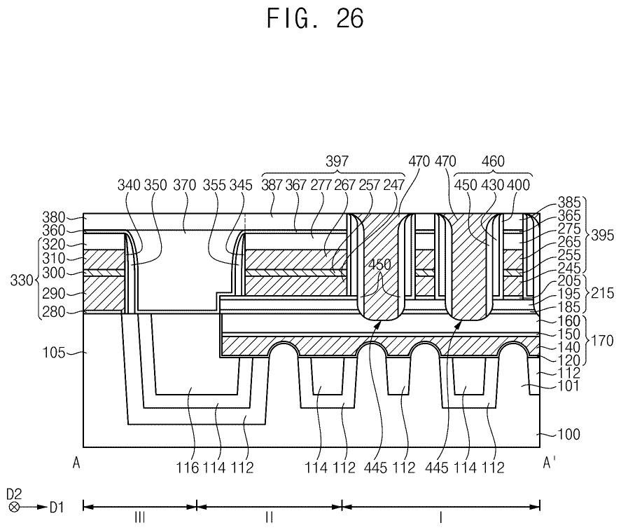

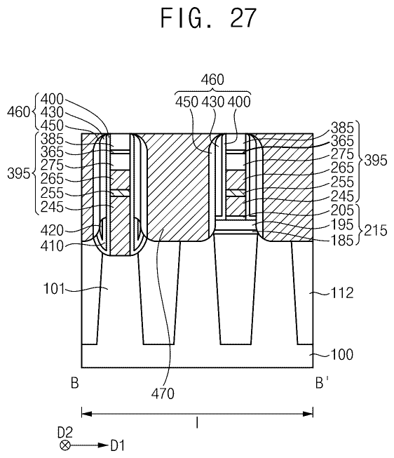

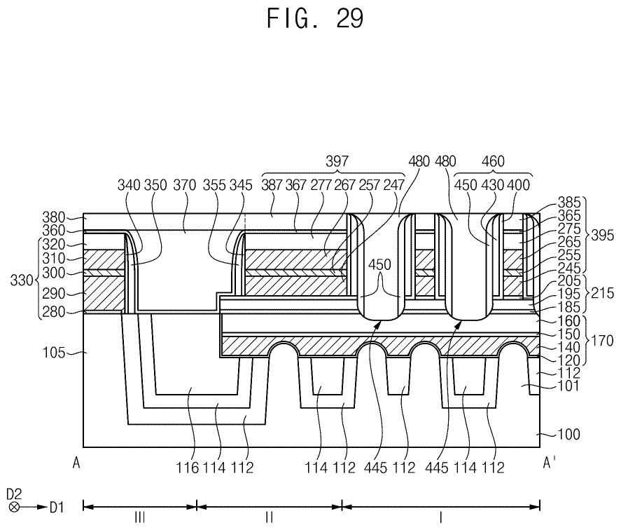

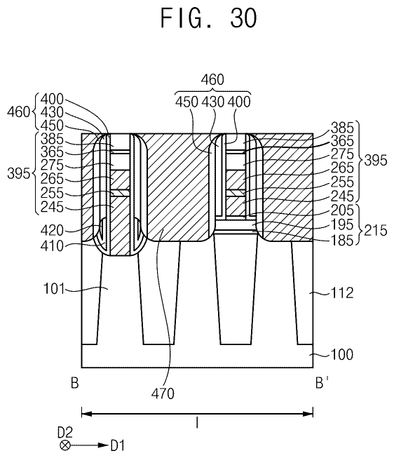

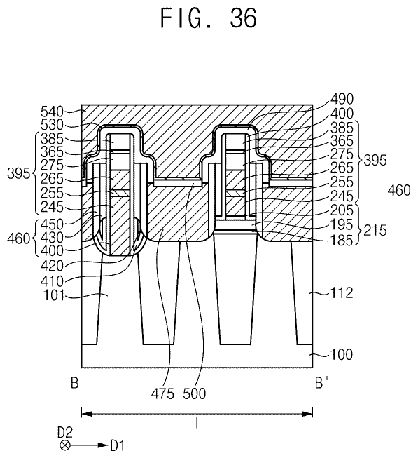

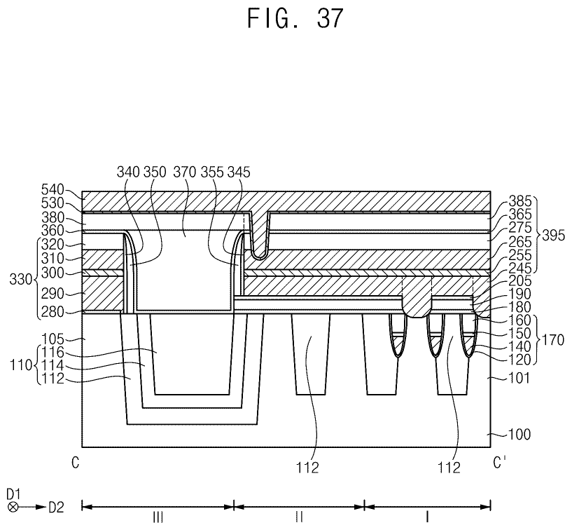

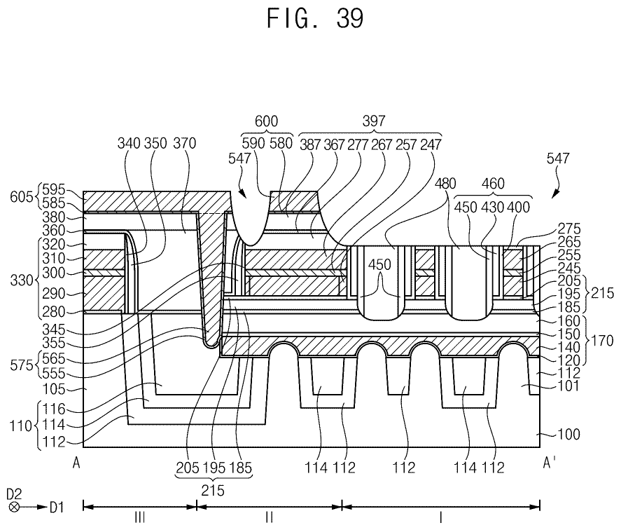

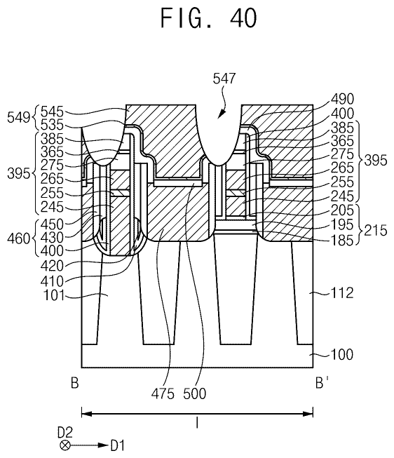

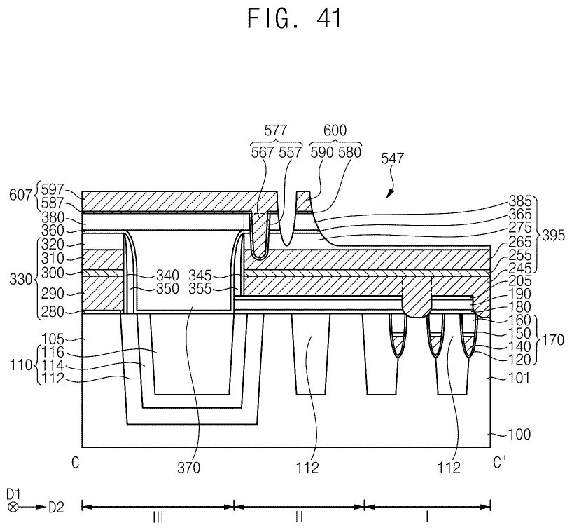

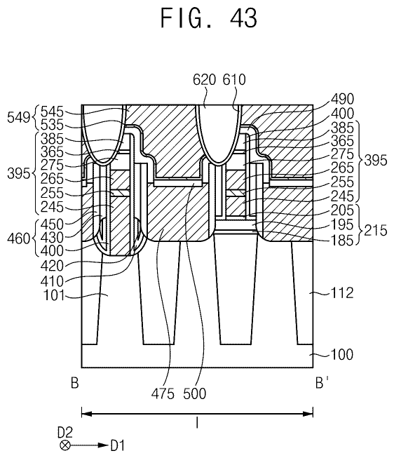

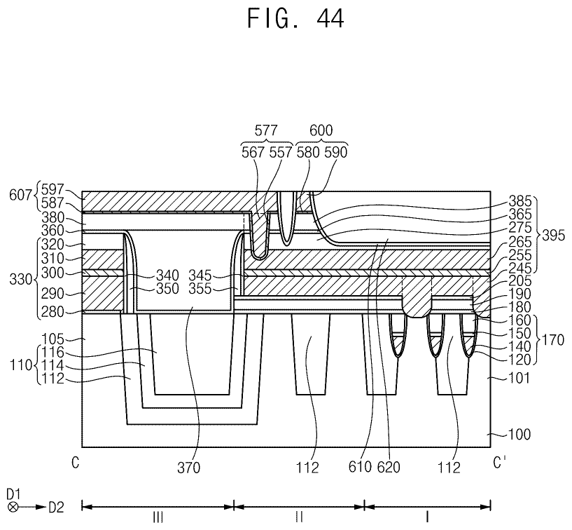

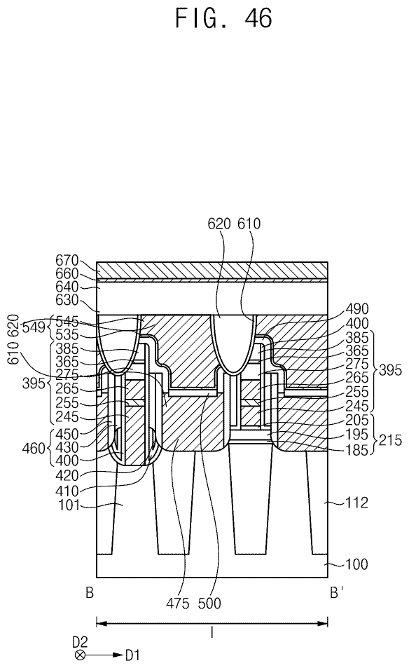

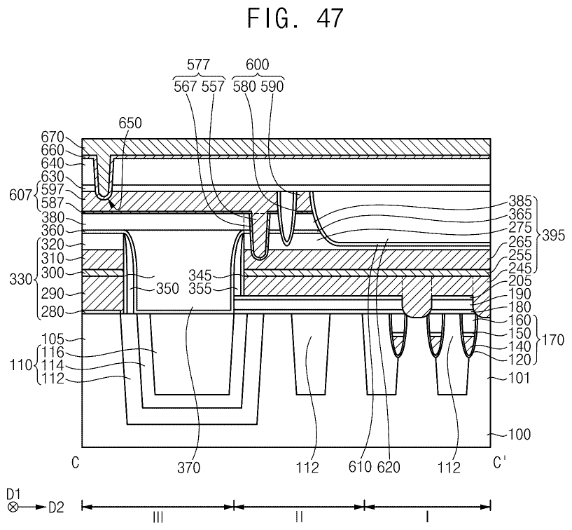

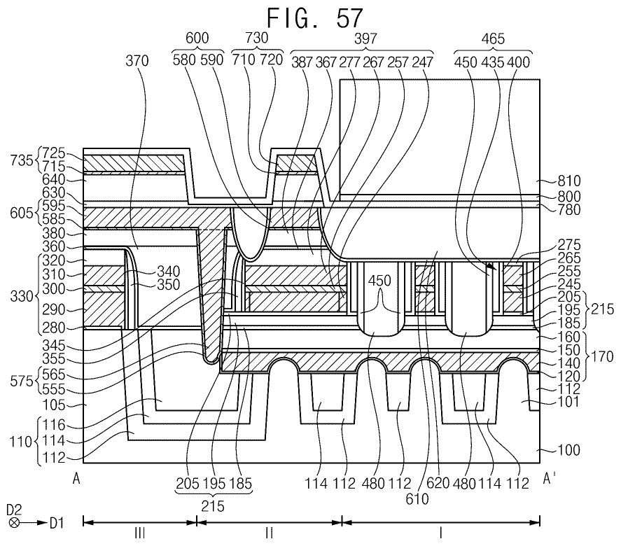

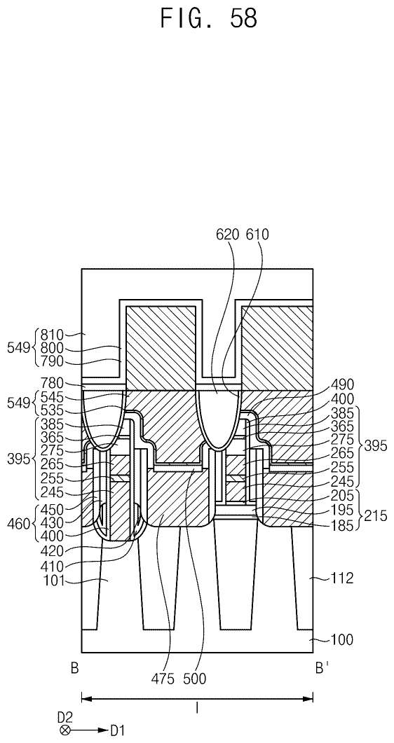

FIGS. 1 to 59 are plan views and cross-sectional views illustrating a method of manufacturing a semiconductor device according to example embodiments. Specifically, FIGS. 1-2, 5, 8, 14, 19, 25, 28, 32, 38, 48, 50, 52 and 56 are the plan views, FIGS. 3, 6, 9, 12, 15, 18, 20, 23, 26, 29, 33, 35, 39, 42, 45 and 57 are cross-sectional views taken along lines A-A′ of corresponding plan views, respectively, FIGS. 10, 13, 16, 21, 24, 27, 30-31, 36, 40, 43, 46 and 58 are cross-sectional views taken along lines B-B′ of corresponding plan views, respectively, and FIGS. 4, 7, 11, 17, 22, 31, 34, 37, 41, 44, 47, 49, 51, 53-55 and 59 are cross-sectional views taken along lines C-C′ of corresponding plan views, respectively. FIGS. 2 to 59 are drawings about region X in FIG. 1.

Hereinafter, in the specification, two directions substantially parallel to an upper surface of a substrate 100 and substantially perpendicular to each other may be referred to as first and second directions D1 and D2, respectively, and a direction substantially parallel to the upper surface of the substrate 100 and having an acute angle with respect to the first and second directions D1 and D2 may be referred to as a third direction D3. Directions substantially parallel to the upper surface of the substrate 100, such as the directions D1, D2, and D3, may be referred to as horizontal directions. A direction substantially perpendicular to the upper surface of the substrate 100 may be referred to as a vertical direction.

Referring to FIGS. 1 to 4, first and second active patterns 101 and 105 may be formed on the substrate 100 including first, second and third regions I, II and III.

The substrate 100 may include silicon, germanium, silicon-germanium, or a I-V group compound semiconductor, such as GaP, GaAs, or GaSb. In example embodiments, the substrate 100 may be a silicon-on-insulator (SOI) substrate or a germanium-on-insulator (GOI) substrate.

The first region I of the substrate 100 may be a cell array region on which memory cells are formed, and the second region II of the substrate 100 may be an extension region. The first and second regions I and II of the substrate 100 may collectively form a cell region. For example, memory cells may be formed on the first region I of the substrate 100, and contact plugs that transmit signals to the memory cells may be formed on the second region II of the substrate 100. The third region III of the substrate 100 surrounding the first and second regions I and II of the substrate 100 may be a peripheral circuit region on which peripheral circuit patterns for driving the memory cells are formed.

The second region II may completely surround the first region I, but the concept of the present invention is not limited thereto. For example, the second region II may be formed only on opposite sides of the first region I in the second direction D2. Likewise, the third region III may completely surround the second region II, but the concept of the present invention is not limited thereto. For example, the third region III may be formed only on opposite sides of the second region II in the second direction D2.

FIGS. 2 to 4 show a portion of the first region I and portions of the second and third regions II and III adjacent to the first region I in the first and second directions D1 and D2.

The first and second active patterns 101 and 105 may be formed by removing an upper portion of the substrate 100 to form a first recess structure.

In example embodiments, the first active pattern 101 may extend in the third direction D3 on the first and second regions I and II of the substrate 100, and a plurality of first active patterns 101 may be spaced apart from each other along each of the first and second directions D1 and D2.

In example embodiments, a plurality of second active patterns 105 may be spaced apart from each other in each of the first and second directions D1 and D2 on the third region III of the substrate 100.

The first recess structure may include first, second and third recesses 102, 104 and 106. In some examples, the first recess 102 may be formed between instances of the first active patterns 101 spaced apart from each other by a relatively small distance on the first and second regions I and II of the substrate 100, the second recess 104 may be formed between instances of the first active patterns 101 spaced apart from each other by a relatively large distance on the first and second regions I and II of the substrate 100, and the third recess 106 may be formed on the second and third regions II and III of the substrate 100.

In example embodiments, the third recess 106 may have a width and/or depth greater than a width and/or depth of the second recess 104, and the second recess 104 may have a width and/or depth greater than a width and/or depth of the first recess 102.

An isolation structure 110 may be formed to cover sidewalls of the first and second active patterns 101 and 105.

In example embodiments, the isolation structure 110 may include first, second and third isolation patterns 112, 114 and 116 sequentially stacked on an inner wall of the third recess 106. However, the first and second isolation patterns 112 and 114 may be formed in the second recess 104 having a width smaller than that of the third recess 106, and the first isolation pattern 112 may be formed in the first recess 102 having a width smaller than that of the second recess 104.

Each of the first and third isolation patterns 112 and 116 may include an oxide, e.g., silicon oxide, and the second isolation pattern 114 may include an insulating nitride, e.g., silicon nitride.

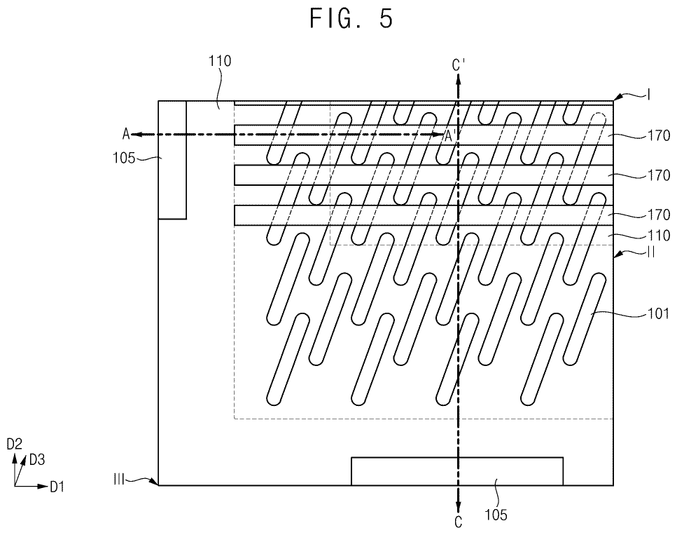

Referring to FIGS. 5 to 7, an etching process may be performed on the first active pattern 101 and the isolation structure 110 on the first region I of the substrate 100 and a portion of the second region II of the substrate 100 adjacent to the first region I of the substrate 100 in the first direction D1, thereby forming a fourth recess 40.

In example embodiments, during the etching process, the first active pattern 101 including a semiconductor material may be less etched than the isolation structure 110 including an insulating material due to the etching selectivity. Thus, the fourth recess 40 may have a concave upper surface on an upper surface of the first active pattern 101.

A first gate insulation layer and a first conductive layer may be sequentially stacked on an inner wall of the fourth recess 40 and upper surfaces of the first and second active patterns 101 and 105. The isolation structure 110, the first gate insulation layer and the first conductive layer may be planarized until the upper surfaces of the first and second active patterns 101 and 105 and the isolation structure 110 are exposed. An upper portion of the first conductive layer may be removed by, e.g., an etch back process.

The planarization process may include a chemical mechanical polishing (CMP) process and/or an etch back process.

By the CMP process, a first gate insulation pattern 120 may be formed on the inner wall of the fourth recess 40, and by the etch back process, a first conductive pattern 140 may be formed on the first gate insulation pattern 120 to fill a lower portion of the fourth recess 40.

A second conductive pattern 150 may be formed on the first conductive pattern 140, a first gate mask layer may be formed on the second conductive pattern 150, the first and second active patterns 101 and 105 and the isolation structure 110 to fill the fourth recess 40, and the first gate mask layer may be planarized until the upper surfaces of the first and second active patterns 101 and 105 and the isolation structure 110 are exposed, so that a first gate mask 160 may be formed to fill an upper portion of the fourth recess 40. The first conductive pattern 140 and the second conductive pattern 150 may collectively form a gate electrode, and a first barrier pattern may be further formed between the first gate insulation pattern 120 and the first conductive pattern 140.

The first gate insulation pattern 120 may include an oxide, e.g., silicon oxide, the first barrier pattern may include a metal nitride, e.g., titanium nitride, tantalum nitride, etc. The first conductive pattern 140 may include a metal, a metal nitride, a metal silicide, doped polysilicon, etc. The second conductive pattern 150 may include doped polysilicon, and the first gate mask 160 may include a nitride, e.g., silicon nitride.

The first gate insulation pattern 120, the first barrier pattern, the first conductive pattern 140, the second conductive pattern 150 and the first gate mask 160 in the fourth recess 40 may collectively form a first gate structure 170.

In example embodiments, the first gate structure 170 may extend in the first direction D1 through end portions in the third direction D3 of the first active patterns 101 both on the first region I of the substrate 100 and on the portion of the second region II of the substrate 100 adjacent to the first region I of the substrate 100 in the first direction D1. A plurality of first gate structures 170 may be spaced apart from each other in the second direction D2. End portions in the first direction D1 of the first gate structures 170 may be aligned with each other in the second direction D2 on the portion of the second region II of the substrate 100.

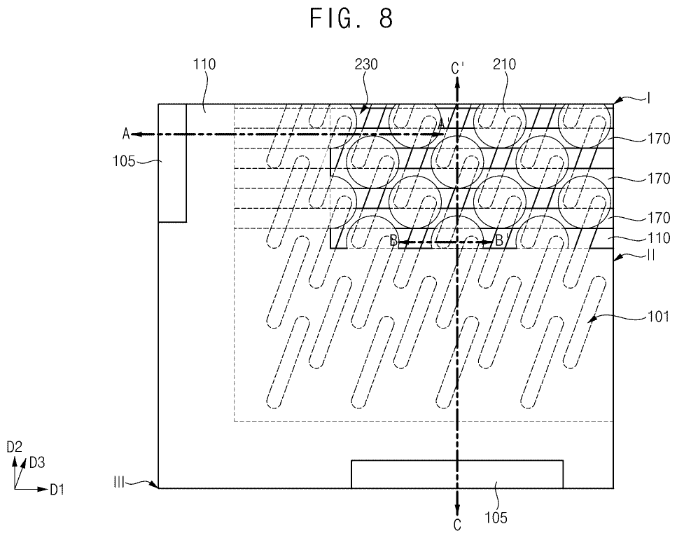

Referring to FIGS. 8 to 11, an insulation layer structure 210 may be formed on the first to third regions I, II and III of the substrate 100, and a portion of the insulation layer structure 210 on the third region III of the substrate 100 may be removed.

For example, a thermal oxidation process may be performed on the second active pattern 105 on the third region III of the substrate 100 to form a second gate insulation layer 220.

The insulation layer structure 210 on the first region I of the substrate 100 may be patterned, and the first active pattern 101, the isolation structure 110, and the first gate mask 160 of the first gate structure 170 may be partially etched using the patterned insulation layer structure 210 as an etching mask to form a first opening 230.

In example embodiments, the patterned insulation layer structure 210 on the first region I of the substrate 100 may have a shape of a circle or an ellipse in a plan view, and a plurality of insulation layer structures 210 may be spaced apart from each other in the first and second directions D1 and D2. Each of the insulation layer structures 210 may overlap opposite end portions in the third direction D3 of the first active patterns 101 in a vertical direction substantially perpendicular to the upper surface of the substrate 100. The insulation layer structure 210 on the second region II of the substrate 100 remaining after the etching process may have, for example, a shape of a plate.

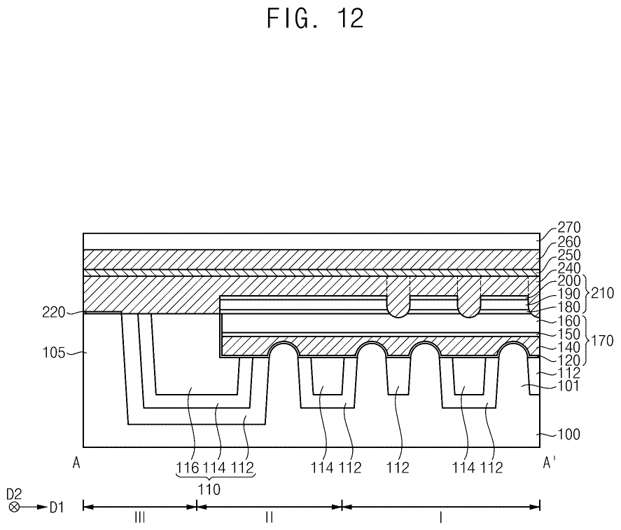

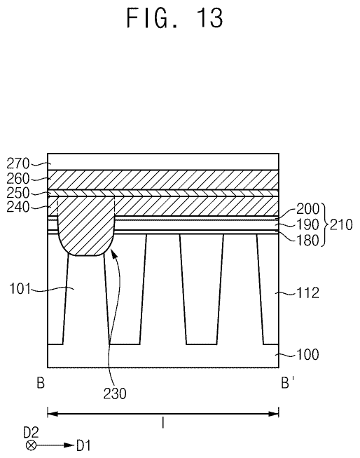

Referring to FIGS. 12 and 13, a third conductive layer 240, a second barrier layer 250, a fourth conductive layer 260 and a second mask layer 270 may be sequentially stacked on the insulation layer structure 210, the upper surfaces of the first active pattern 101, the isolation structure 110 and the first gate structure 170 exposed by the first opening 230 on the first and second regions I and II of the substrate 100, and the second gate insulation layer 220 and the isolation structure 110 on the third region III of the substrate 100, which may collectively form a conductive structure layer. The third conductive layer 240 may fill the first opening 230.

The third conductive layer 240 may include doped polysilicon, the second barrier layer 250 may include a metal silicon nitride, e.g., titanium silicon nitride, the fourth conductive layer 260 may include a metal, e.g., tungsten, and the second mask layer 270 may include a nitride, e.g., silicon nitride.

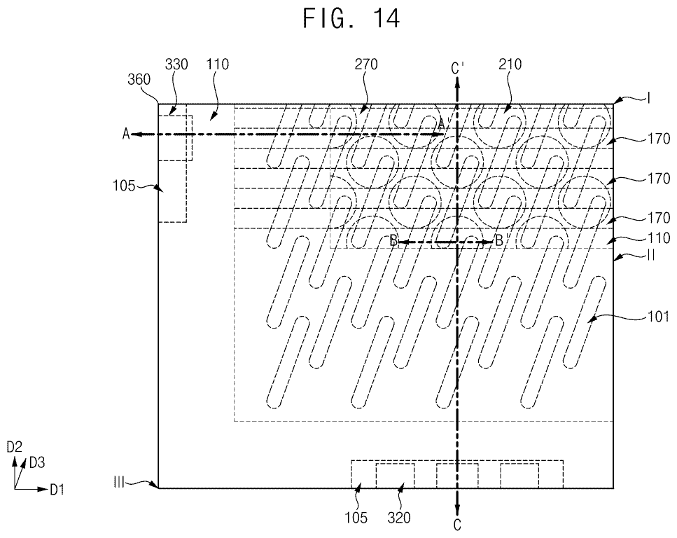

Referring to FIGS. 14 to 17, the conductive structure layer may be patterned to form a second gate structure 330 on the third region III of the substrate 100.

The second gate structure 330 may include a second gate insulation pattern 280, a third conductive pattern 290, a second barrier pattern 300, a fourth conductive pattern 310 and a second gate mask 320 sequentially stacked in the vertical direction substantially perpendicular to an upper surface of the substrate 100, and the third conductive pattern 290, the second barrier pattern 300 and the fourth conductive pattern 310 may collectively form a second gate electrode associated with the second gate structure 330.

The second gate structure 330 may at least partially overlap the second active pattern 105 in the vertical direction on the third region III of the substrate 100.

A first spacer structure may be formed on a sidewall of the second gate structure 330, and a second spacer structure may be formed on a sidewall of the conductive structure layer remaining on the first and second regions I and II of the substrate 100. The first spacer structure may include first and third spacers 340 and 350 stacked on the sidewall of the second gate structure 330 in a horizontal direction substantially parallel to the upper surface of the substrate 100, and the second spacer structure may include second and fourth spacers 345 and 355 stacked on the sidewall of the conductive structure layer in the horizontal direction.

The first and second spacers 340 and 345 may be formed by forming a first spacer layer on the substrate 100 to cover the conductive structure layer and the second gate structure 330 and anisotropically etching the first spacer layer. The third and fourth spacers 350 and 355 may be formed by forming a second spacer layer on the substrate 100 to cover the conductive structure layer, the second gate structure 330 and the first and second spacers 340 and 345 and anisotropically etching the second spacer layer.

The first and second spacers 340 and 345 may include a nitride, e.g., silicon nitride, and the third and fourth spacers 350 and 355 may include an oxide, e.g., silicon oxide.

However, the structure of the first and second spacer structures may not be limited thereto, and each of the first and second spacer structures may include a single spacer or more than two spacers sequentially stacked.

A first etch stop layer 360 may be formed on the substrate 100 to cover the conductive structure layer, the second gate structure 330, the first and second spacer structures, and the isolation structure 110. The first etch stop layer 360 may include a nitride, e.g., silicon nitride.

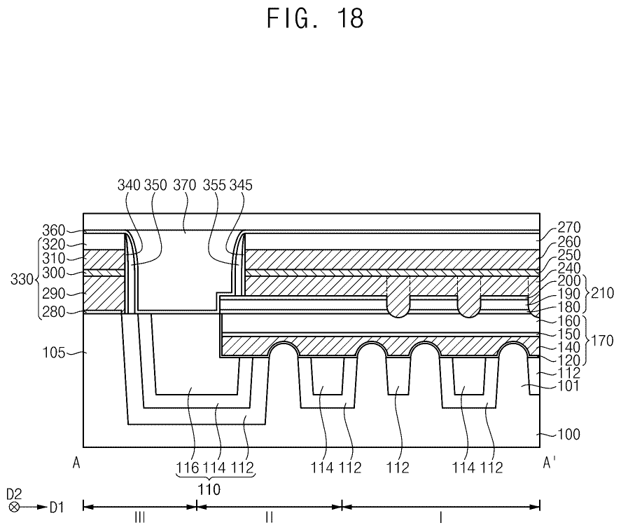

Referring to FIG. 18, a first insulating interlayer 370 may be formed on the first etch stop layer 360 to a sufficient height, the first insulating interlayer 370 may be planarized until an upper surface of the second gate structure 330 and an upper surface of a portion of the first etch stop layer 360 on the conductive structure layer are exposed, and a capping layer 380 may be formed on the first insulating interlayer 370 and the first etch stop layer 360.

Thus, the first insulating interlayer 370 may fill a space between the first spacer structures on the sidewall of the second gate structures 330, and a space between the first spacer structure on the sidewall of the second gate structure 330 and the second spacer structure on the sidewall of the conductive structure layer.

The first insulating interlayer 370 may include an oxide, e.g., silicon oxide, and the capping layer 380 may include a nitride, e.g., silicon nitride.

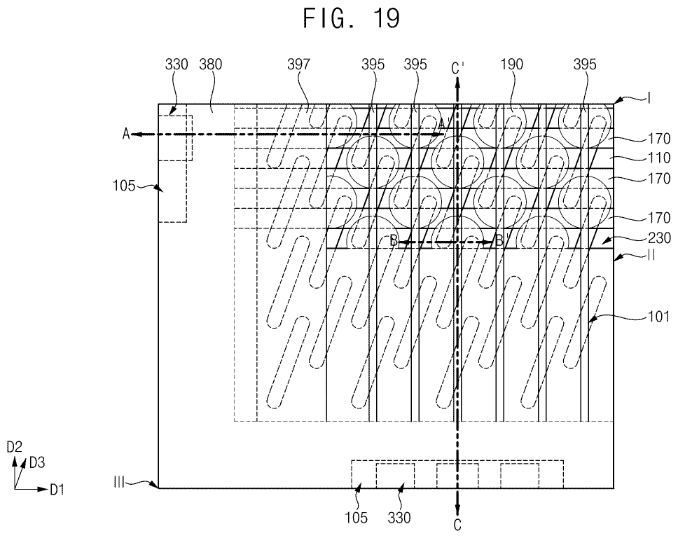

Referring to FIGS. 19 to 22, a portion of the capping layer 380 on the first region I of the substrate 100 may be etched to form a first capping pattern 385, and the first etch stop layer 360, the second mask layer 270, the fourth conductive layer 260, the second barrier layer 250 and the third conductive layer 240 may be sequentially etched using the first capping pattern 385 as an etching mask.

In example embodiments, the first capping pattern 385 may extend in the second direction D2 both on the first region I of the substrate 100 and on a portion of the second region

II of the substrate 100 adjacent to the first region I of the substrate 100 in the second direction D2, and a plurality of first capping patterns 385 may be formed to be spaced apart from each other in the first direction D1. The capping layer 380 may remain on the third region III of the substrate 100.

By the etching process, on the first region I of the substrate 100 and the portion of the second region II of the substrate 100 adjacent to the first region I of the substrate 100 in the second direction D2, a fifth conductive pattern 245, a third barrier pattern 255, a sixth conductive pattern 265, a second mask 275, a first etch stop pattern 365 and the first capping pattern 385 may be sequentially stacked on the first opening 230, and a third insulation pattern 205, the fifth conductive pattern 245, the third barrier pattern 255, the sixth conductive pattern 265, the second mask 275, the first etch stop pattern 365 and the first capping pattern 385 may be sequentially stacked on the second insulation layer 190 of the insulation layer structure 210 at an outside of the first opening 230.

Hereinafter, the fifth conductive pattern 245, the third barrier pattern 255, the sixth conductive pattern 265, the second mask 275, the first etch stop pattern 365 and the first capping pattern 385 sequentially stacked may be referred to as a bit line structure 395. In example embodiments, the bit line structure 395 may extend in the second direction D2 on the first and second regions I and II of the substrate 100, and a plurality of bit line structures 395 may be spaced apart from each other in the first direction D1.

A dummy bit line structure 397 including a seventh conductive pattern 247, a fourth barrier pattern 257, an eighth conductive pattern 267, a third mask 277, a second etch stop pattern 367 and a second capping pattern 387 sequentially stacked and extending in the second direction D2 may be formed on a portion of the first region I of the substrate 100 adjacent to the second region II of the substrate 100 in the first direction D1.

The first etch stop layer 360 may remain on the second gate structure 330, the first and second spacer structures, a portion of the insulation layer structure 210, the second active pattern 105 and the isolation structure 110. Additionally, the capping layer 380 may remain on portions of the first etch stop layer 360 on an upper surface of the second gate structure 330 and the first insulating interlayer 370.

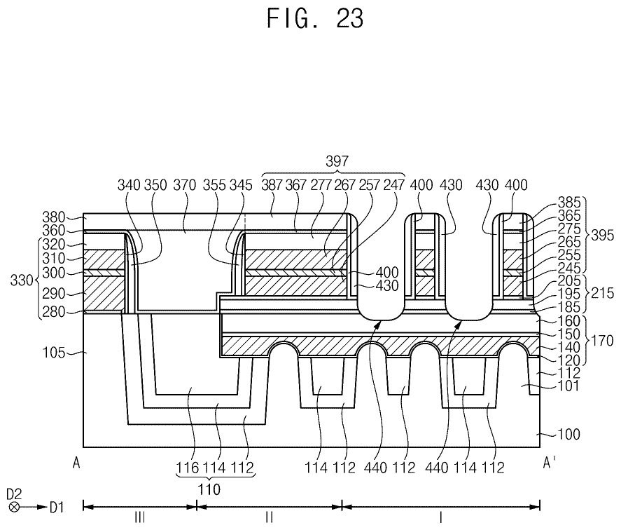

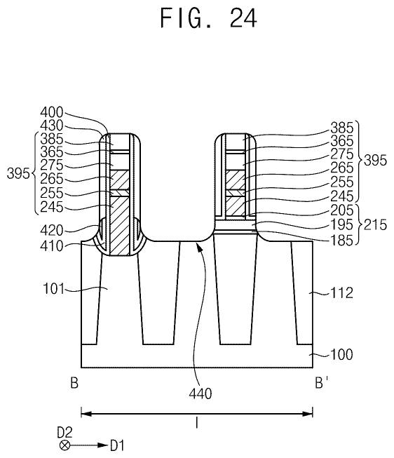

Referring to FIGS. 23 and 24, a fifth spacer layer may be formed on the substrate 100 to cover the bit line structure 395, the dummy bit line structure 397 and the capping layer 380, and fourth and fifth insulation layers may be sequentially formed on the fifth spacer layer.

The fifth spacer layer may also cover a sidewall of the third insulation pattern 205 between the second insulation layer 190 and the bit line structure 395, and the fifth insulation layer may fill the first opening 230.

The fifth spacer layer may include a nitride, e.g., silicon nitride, the fourth insulation layer may include an oxide, e.g., silicon oxide, and the fifth insulation layer may include a nitride, e.g., silicon nitride.

The fourth and fifth insulation layers may be etched by an etching process. In example embodiments, the etching process may be performed by a wet etch process using an etching solution including phosphorous acid (H₃PO₄), SC1, hydrogen fluoride (HF), and other portions of the fourth and fifth insulation layers except for a portion in the first opening 230 may be removed. Thus, most of an entire surface of the fifth spacer layer, for example, an entire surface except for a portion thereof in the first opening 230 may be exposed, and portions of the fourth and fifth insulation layers remaining in the first opening 230 may form fourth and fifth insulation patterns 410 and 420, respectively.

A sixth spacer layer may be formed on the exposed surface of the fifth spacer layer and the fourth and fifth insulation patterns 410 and 420 in the first opening 230, and may be anisotropically etched to form a sixth spacer 430 on the surface of the fifth spacer layer and the fourth and fifth insulation patterns 410 and 420 to cover a sidewall of the bit line structure 395. In some examples, the sixth spacer layer may also be formed on a sidewall of the dummy bit line structure 397. The sixth spacer layer may include an oxide, e.g., silicon oxide.

A dry etching process may be performed to form a second opening 440 exposing the upper surface of the first active pattern 101 on the first region I of the substrate 100. An upper surface of the isolation structure 110 and an upper surface of the first gate mask 160 may also be exposed by the second opening 440.

By the dry etching process, portions of the fifth spacer layer on upper surfaces of the first and second capping patterns 385 and 387, the second insulation layer 190 and the capping layer 380 may be removed, and thus a fifth spacer 400 covering the sidewall of the bit line structure 395 may be formed. The fifth spacer 400 may also cover the sidewall of the dummy bit line structure 397.

Additionally, during the dry etching process, the first and second insulation layers 180 and 190 may be partially removed, such that first and second insulation patterns 185 and 195 may remain under the bit line structure 395. The first to third insulation patterns 185, 195 and 205 that are sequentially stacked under the bit line structure 395 may collectively form an insulation pattern structure 215.

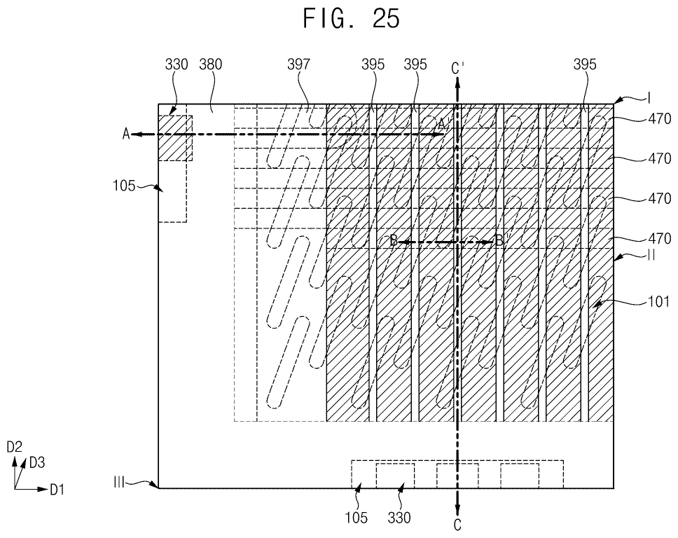

Referring to FIGS. 25 to 27, a seventh spacer layer may be formed on the upper surface of the first and second capping patterns 385 and 387, the upper surface of the capping layer 380, an outer sidewall of the sixth spacer 430, portions of upper surfaces of the fourth and fifth insulation patterns 410 and 420, and the upper surfaces of the first active pattern 101, the isolation structure 110 and the first gate mask 160 exposed by the second opening 440, and may be anisotropically etched to form a seventh spacer 450 covering an outer sidewall of sixth spacer 430 on the sidewalls of the bit line structure 395 and the dummy bit line structure 397. The seventh spacer layer may include a nitride, e.g., silicon nitride.

The fifth to seventh spacers 400, 430 and 450 sequentially stacked in the horizontal direction from the sidewall of the bit line structure 395 on the first and second regions I and II of the substrate 100 may be referred to as a preliminary third spacer structure 460.

One or more first lower contact plug layer 470 may be formed on the first region I of the substrate 100 to a sufficient height to fill the second opening 440, and the first lower contact plug layer 470 may be planarized until the upper surfaces of the capping layer 380 and the first and second capping patterns 385 and 387 are exposed.

The first lower contact plug layer 470 may extend in the second direction D2 between neighboring instances of the bit line structures 395 in the first direction D1 and between the bit line structure 395 and the dummy bit line structure 397 on the first region I of the substrate 100 and the portion of the second region II of the substrate 100 adjacent to the first region I of the substrate 100 in the second direction D2. A plurality of first lower contact plug layers 470 may be spaced apart from each other along the first direction D1. Each of the first lower contact plug layers 470 may contact an upper surface of an end portion in the third direction D3 of the first active pattern 101 extending in the third direction D3.

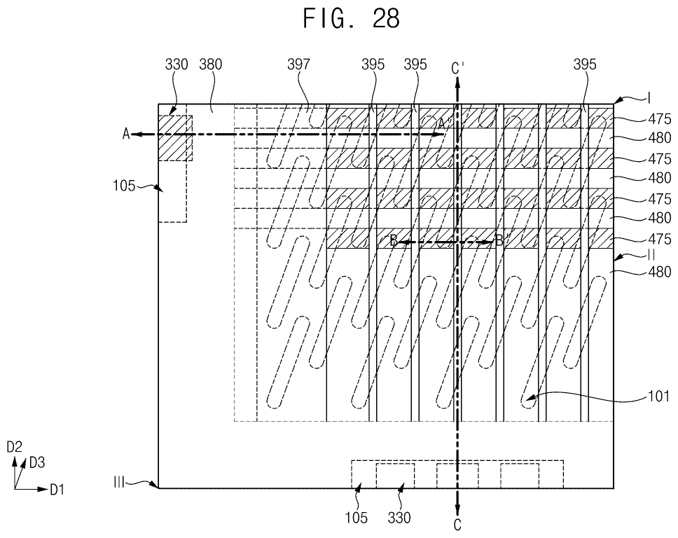

Referring to FIGS. 28 to 30, an etching mask having third openings, each of which may extend in the first direction D1, spaced apart from each other in the second direction D2 may be formed on the capping layer 380, the bit line structure 395, the dummy bit line structure 397 and the first lower contact plug layer 470, and an etching process may be performed on the first lower contact plug layer 470 using the etching mask to form a fourth opening 445.

In example embodiments, the third opening may overlap the first gate structure 170 in the vertical direction on the first region I of the substrate 100 and a portion of the first lower contact plug layer 470 on the second region II of the substrate 100. Accordingly, the fourth opening 445 may expose an upper surface of the first gate mask 160 of the first gate structure 170 on the first region I of the substrate 100 and the second insulation layer 190 on the second region II of the substrate 100. As the fourth opening 445 is formed, the first lower contact plug layer 470 extending in the second direction D2 may be divided into a plurality of first lower contact plugs 475 spaced apart from each other in the second direction D2 on the first region I of the substrate 100.

After removing the etching mask, at least one fence pattern 480 may be formed to fill the fourth opening 445. A plurality of fence patterns 480 may be spaced apart from each other in the second direction D2 between the bit line structures 395 and between the bit line structure 395 and the dummy bit line structure 397 on the first region I of the substrate 100, and may extend in the second direction D2 between the bit line structures 395 and between the bit line structure 395 and the dummy bit line structure 397 on the second region II of the substrate 100. The fence pattern 480 may include a nitride, e.g., silicon nitride.

As illustrated above, the first lower contact plugs 475 and the fence patterns 480 that may be alternately and repeatedly arranged in the second direction D2 may be formed by forming the first lower contact plug layer 470 extending in the second direction D2 between the bit line structures 395, planarizing an upper portion of the first lower contact plug layer 470, forming the fourth openings 445 through the first lower contact plug layer 470 that are spaced apart from each other in the second direction D2, and filling the fourth opening 445 by the fence pattern 480, however, the inventive concept may not be limited thereto.

Alternatively, the first lower contact plugs 475 and the fence patterns 480 that may be alternately and repeatedly arranged in the second direction D2 may be formed by forming a fence layer extending in the second direction D2 between the bit line structures 395, forming fifth openings through the fence layer spaced apart from each other in the second direction D2 to divide the fence layer into the fence patterns 480, forming the first lower contact plug layer 470 on the fence layer to fill the fifth openings, and planarizing the first lower contact plug layer 470 to form the first lower contact plugs 475.

Alternatively, the first lower contact plugs 475 and the fence patterns 480 that may be alternately and repeatedly arranged in the second direction D2 may be formed by forming a sacrificial layer including an oxide, e.g., silicon oxide, and extending in the second direction D2 between the bit line structures 395, forming the fence patterns 480 through the sacrificial layer spaced apart from each other in the second direction D2, removing the sacrificial layer to form sixth openings, forming the first lower contact plug layer 470 to fill the sixth openings, and planarizing the first lower contact plug layer 470 to form the first lower contact plugs 475.

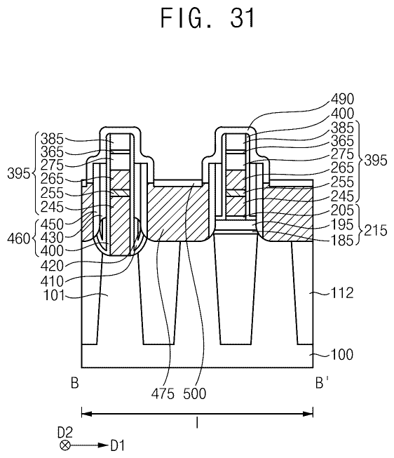

Referring to FIG. 31, an upper portion of the first lower contact plug 475 may be removed to expose an upper portion of the preliminary third spacer structure 460 on the sidewalls of the bit line structure 395 and the dummy bit line structure 397, and upper portions of the sixth and seventh spacers 430 and 450 of the exposed preliminary third spacer structure 460 may be removed.

An etch back process may be further performed to remove an upper portion of the first lower contact plug 475. Thus, an upper surface of the first lower contact plug 475 may be lower than uppermost surfaces of the sixth and seventh spacers 430 and 450.

An eighth spacer layer may be formed on the bit line structure 395, the dummy bit line structure 397, the preliminary third spacer structure 460, the fence pattern 480, the capping layer 380, and the first lower contact plug 475, and may be anisotropically etched. Accordingly, an eighth spacer 490 may be formed to cover the preliminary third spacer structure 460 on each of opposite sidewalls of the bit line structure 395 in the first direction D1, and an upper surface of the first lower contact plug 475 may not be covered to be exposed.

An ohmic contact pattern 500 may be formed on the exposed upper surface of the lower contact plug 475. In example embodiments, the ohmic contact patterns 500 may be formed by forming a first metal layer on the first and second capping patterns 385 and 387, the capping layer 380, the fence pattern 480, the eighth spacer 490, and the first lower contact plug 475, thermally treating the first metal layer, and removing an unreacted portion of the first metal layer. The ohmic contact patterns 500 may include a metal silicide, e.g., cobalt silicide, nickel silicide, titanium silicide, etc.

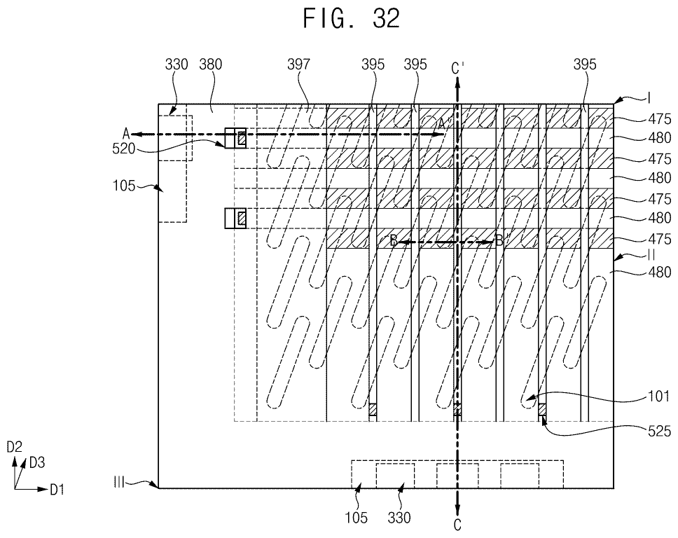

Referring to FIGS. 32 to 34, a seventh opening 520 may be formed through a portion of the capping layer 380 on the portion of the second region II of the substrate 100 adjacent to the first region I of the substrate 100 in the first direction D1, the first insulating interlayer 370, the first etch stop layer 360, the insulation pattern structure 215, the isolation structure 110, the first gate mask 160 and the second conductive pattern 150 to expose the first conductive pattern 140, and the seventh opening 520 may also expose the first gate insulation pattern 120 on the sidewall of the first conductive pattern 140. An eighth opening 525 may be formed through the first capping pattern 385 on the portion of the second region II of the substrate 100 adjacent to the first region I of the substrate 100 in the second direction D2, the first etch stop pattern 365 and the second mask 275 to expose the sixth conductive pattern 265.

In example embodiments, the seventh opening 520 may be formed to overlap in the vertical direction an end portion in the first direction D1 of the first gate structure 170.

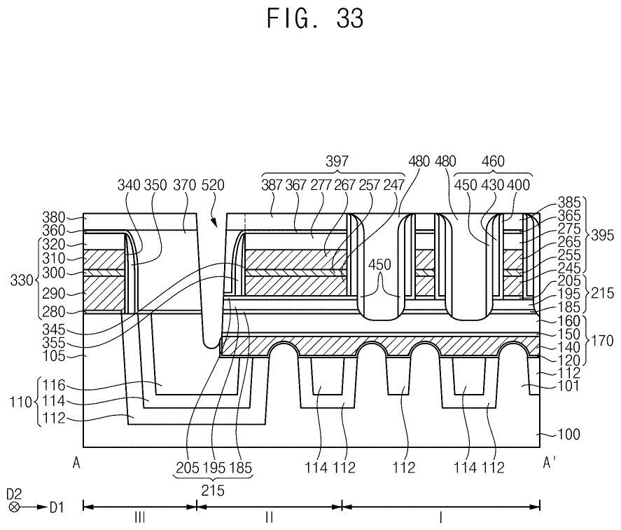

Accordingly, a plurality of seventh openings 520 may be spaced apart from each other in the second direction D2 on the second region II of the substrate 100 along a boundary of the second and third regions II and III of the substrate 100. The seventh opening 520 may overlap in the vertical direction the end portions in the first direction D1, that is leftwards or towards A in FIGS. 32 and 33, of odd-numbered instances of the first gate structures 170, and the end portions in the first direction D1, that is rightwards or towards A′, of even-numbered instances of the first gate structures 170, but the concept of the present invention is not limited thereto, and the seventh opening 520 may be arranged in various layouts.

In example embodiments, the eighth opening 525 may be formed to overlap in the vertical direction an end portion in the second direction D2 of the bit line structure 395.

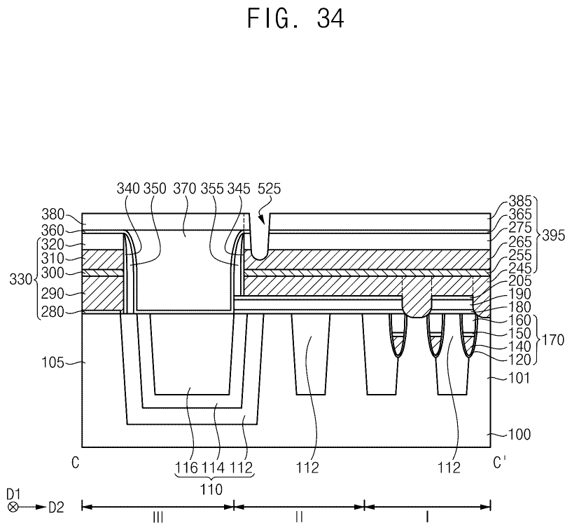

Accordingly, there may be a plurality of eighth openings 525 as illustrated in FIG. 32, and the eighth openings 525 may be spaced apart from each other in the first direction D1 on the second region II of the substrate 100 along a boundary of the second and third regions II and III of the substrate 100. The eighth opening 525 may overlap in the vertical direction the end portions in the second direction D2, that is downwards or towards C in FIG. 32, or leftwards or towards C in FIG. 34, of odd-numbered instances of the bit line structures 395 and the end portions in the second direction D2, that is upwards or towards C′ in FIG. 32, or rightwards or towards C′ in

FIG. 34, of even-numbered instances of the bit line structures 395, but the concept of the present invention is not limited thereto, and the eighth opening 525 may be arranged in various layouts.

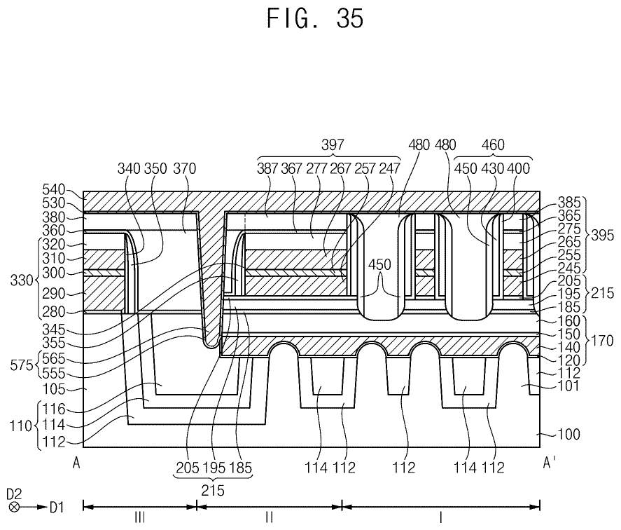

Referring to FIGS. 35 to 37, a fifth barrier layer 530 may be formed on the first and second capping patterns 385 and 387, the fence pattern 480, the eighth spacer 490, the ohmic contact pattern 500, the first lower contact plug 475, a sidewall of the seventh opening 520 and the isolation structure 110, the first conductive pattern 140 and the first gate insulation pattern 120 exposed by the seventh opening 520, and a sidewall of the eighth opening 525 and the sixth conductive pattern 265 exposed by the eighth opening 525 on the first and second regions I and II of the substrate 100. A second metal layer 540 may be formed on the fifth barrier layer 530 to fill a space between the bit line structures 395, between the bit line structure 395 and the dummy bit line structure 397, and the seventh and eighth openings 520 and 525.

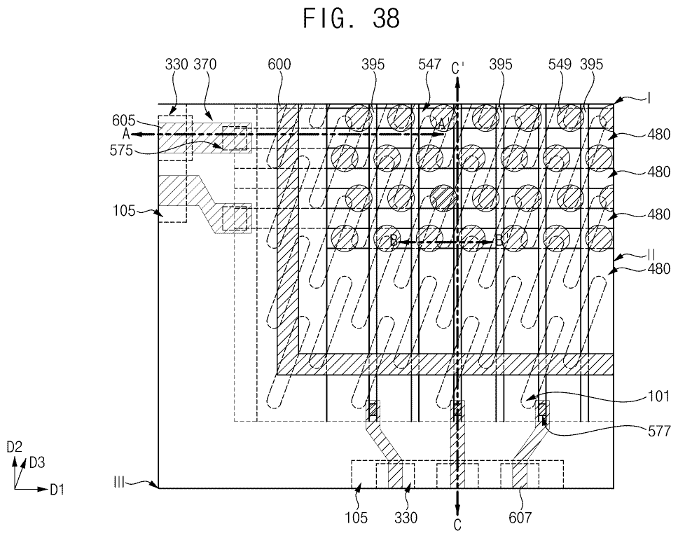

Referring to FIGS. 38 to 41, the second metal layer 540 and the fifth barrier layer 530 may be patterned.

For example, a second lower contact plug 549 may be formed on the first region I of the substrate 100, and a first lower wiring 600 may be formed on the second region II of the substrate 100. Additionally, a second lower wiring 605 may be formed on portions of the second and third regions II and III of the substrate 100 adjacent to the first region I of the substrate 100 in the first direction D1, and a third lower wiring 607 may be formed on portions of the second and third regions II and III of the substrate 100 adjacent to the first region I of the substrate 100 in the second direction D2. A ninth opening 547 may be formed between the second lower contact plug 549 and the first to third lower wirings 600, 605 and 607.

The ninth opening 547 may be formed by removing not only the second metal layer 540 and the fifth barrier layer 530 but also the first and second capping patterns 385 and 387, the fence pattern 480, the capping layer 380, the preliminary third spacer structure 460, the eighth spacer 490, the first etch stop layer 360, the first etch stop pattern 365, and the second mask 275. Accordingly, an upper surface of the sixth spacer 430 may be exposed.

As the ninth opening 547 is formed, the second metal layer 540 and the fifth barrier layer 530 may, respectively, be transformed into a first metal pattern 545 and a fifth barrier pattern 535 covering a lower surface of the first metal pattern 545, which may collectively form a second lower contact plug 549 on the first region I of the substrate 100. In example embodiments, a plurality of second lower contact plugs 549 may be formed to be spaced apart from each other in each of the first and second directions D1 and D2, and may be arranged in a honeycomb pattern or a lattice pattern in a plan view. Each of the second lower contact plugs 549 may have a shape of a circle, an ellipse, or a polygon in a plan view.

The first lower contact plug 475, the ohmic contact pattern 500 and the second lower contact plug 549 sequentially stacked on the first region I of the substrate 100 may collectively form a first lower contact plug structure.

The first lower wiring 600 may include a fourth metal pattern 590 and an eighth barrier pattern 580 covering a lower surface of the fourth metal pattern 590. In example embodiments, the first lower wiring 600 may have a shape of a ring in a plan view. Specifically, the first lower wiring 600 may include a first extension portion extending in the second direction D2 on the portion of the second region II of the substrate 100 adjacent to the first region I of the substrate 100 in the first direction D1, and a second extension portion extending in the first direction D1 on the portion of the second region II of the substrate 100 adjacent to the first region I of the substrate 100 in the second direction D2. Accordingly, in a plan view, the first lower wiring 600 may have a shape of a square ring comprising two first extension portions facing each other in the first direction D1 and two second extension portions facing each other in the second direction D2.

The second lower wiring 605 may include a fifth metal pattern 595 and a ninth barrier pattern 585 covering a lower surface of the fifth metal pattern 595. A third lower contact plug 575 including a second metal pattern 565 and a sixth barrier pattern 555 may be formed in the seventh opening 520.

In example embodiments, the second lower wiring 605 may overlap the seventh opening 520 in the vertical direction, and a plurality of second lower wirings 605 may be spaced apart from each other in the second direction D2. The second lower wiring 605 may be electrically connected to the first conductive pattern 140 through the third lower contact plug 575, and thus may apply electrical signals to the first gate structure 170.

The third lower wiring 607 may include a sixth metal pattern 597 and a tenth barrier pattern 587 covering a lower surface of the sixth metal pattern 597. A fourth lower contact plug 577 including a third metal pattern 567 and a seventh barrier pattern 557 may be formed in the eighth opening 525.

In example embodiments, the third lower wiring 607 may overlap the eighth opening 525 in the vertical direction, and a plurality of third lower wirings 607 may be spaced apart from each other in the first direction D1. The third lower wiring 607 may be electrically connected to the sixth conductive pattern 265 through the fourth lower contact plug 577, and thus may apply electrical signals to the bit line structure 395.

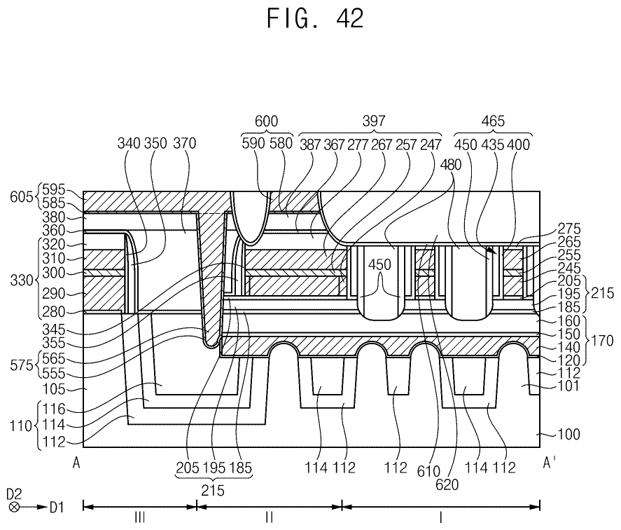

Referring to FIGS. 42 to 44, the sixth spacer 430 may be removed to form an air gap 435 connected to the ninth opening 547. The sixth spacer 430 may be removed by, e.g., a wet etching process.

In example embodiments, not only a first portion of the sixth spacer 430 on the sidewalls of the bit line structure 395 and the dummy bit line structure 397, which is directly exposed by the ninth opening 547, but also a second portion of the sixth spacer 430, which is parallel to the first portion in the horizontal direction, may be removed. For example, not only a portion of the sixth spacer 430 exposed by the ninth opening 547 not covered by the second lower contact plug 549 but also a portion of the sixth spacer 430 covered by the second lower contact plug 549 may be removed.

A second insulating interlayer may be formed to fill the ninth opening 547.

In example embodiments, the second insulating interlayer may include sixth and seventh insulation layers 610 and 620 sequentially stacked. The sixth insulation layer 610 may include a material having a poor gap filling characteristic, and thus the air gap 435 may not be filled with the sixth insulation layer 610, but may remain, which may be referred to as an air spacer 435. The fifth and seventh spacers 400 and 450 and the air spacer 435 may collectively form a third spacer structure 465. The air spacer 435 may be a spacer, which may contain air. The seventh insulation layer 620 may include an oxide, e.g., silicon oxide or a nitride, e.g., a silicon nitride.

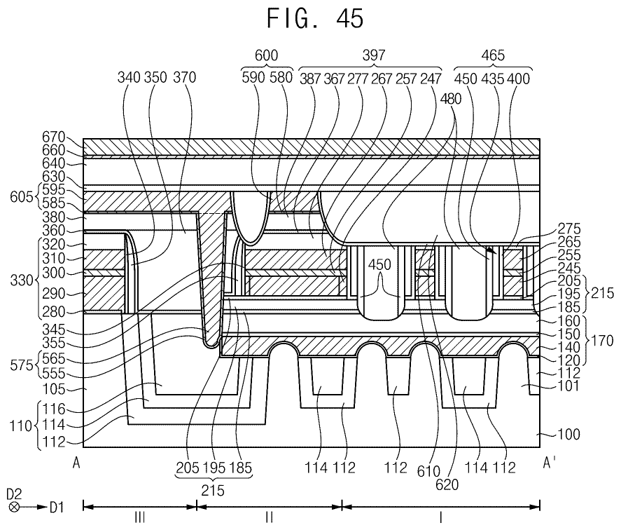

Referring to FIGS. 45 to 47, a second etch stop layer 630 and the first mold layer 640 may be sequentially formed on the first to third lower wirings 600, 605 and 607 and the sixth and seventh insulating layers 610 and 620. In example embodiments, the second etch stop layer 630 may include, e.g., an insulating nitride such as silicon nitride (SiN), silicon carbonitride (SiCN), silicon boron nitride (SiBN), etc., and the first mold layer 640 may include, e.g., TEOS (Tetraethyl Orthosilicate), etc.

A tenth opening and the eleventh opening 650 may be formed to extend through the first mold layer 640 and the second etch stop layer 630 to expose the fifth metal pattern 595 and the sixth metal pattern 597, respectively.

A sixth barrier layer 660 may be formed on the first mold layer 640, a sidewall of the tenth opening and the fifth metal pattern 595 exposed thereby, and a sidewall of the eleventh opening 650 and the sixth metal pattern 597 exposed thereby, and a third metal layer 670 may be formed on the sixth barrier layer 660 to fill the tenth opening and the eleventh opening 650.

In example embodiments, the sixth barrier layer 660 may include, e.g., a metal nitride such as titanium nitride, tantalum nitride, etc., and the third metal layer 670 may include, e.g., a metal such as tungsten, etc.

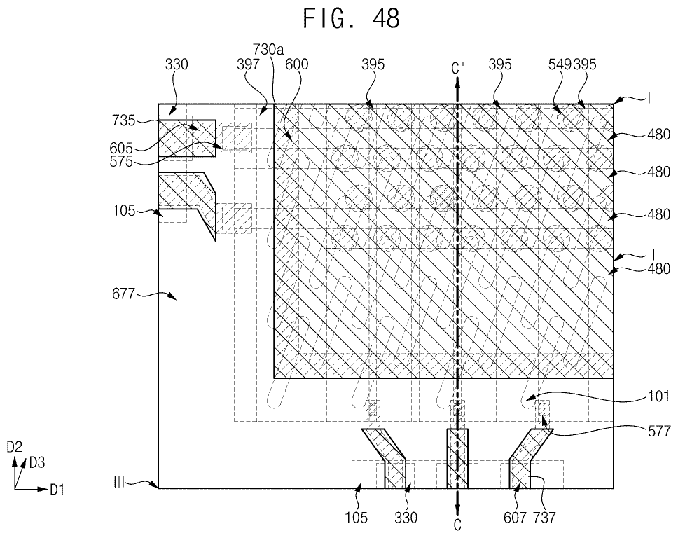

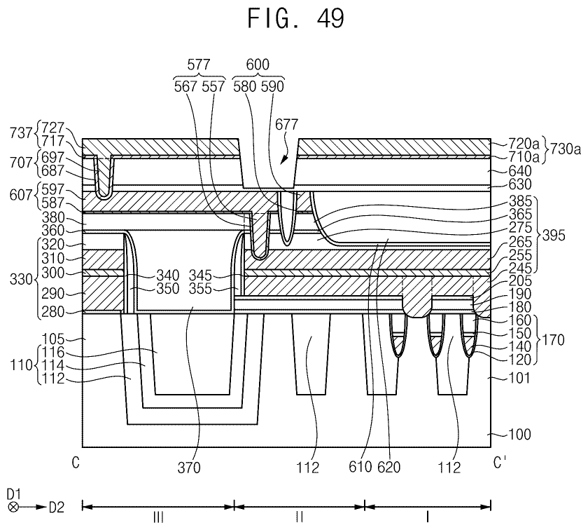

Referring to FIGS. 48 and 49, a first etching process may be performed to pattern the third metal layer 670 and the sixth barrier layer 660. The second etch stop layer 630 may serve as an etch stop layer during the first etching process.

By the first etching process, a preliminary first upper wiring 730a may be formed on the first region I of the substrate 100 and the second region II of the substrate 100 adjacent thereto. A second upper wiring 735 may be formed on a portion of the third region III adjacent to the first and second regions I and II of the substrate 100 in the first direction D1. A third upper wiring 737 may be formed on a portion of the third region III of the substrate 100 adjacent to the first and second regions I and II of the substrate 100 in the second direction D2. A twelfth opening 677 may be formed between the preliminary first upper wiring 730a and the second and third upper wirings 735 and 737.

The twelfth opening 677 may be formed by not only partially removing the third metal layer 670 and the sixth barrier layer 660, but also the first mold layer 640 and an upper portion of the second etch stop layer 630.

As the twelfth opening 677 is formed, the third metal layer 670 and the sixth barrier layer 660 on the first region I of the substrate 100 and the second region II of the substrate 100 adjacent thereto may, respectively, be transformed into a preliminary seventh metal pattern 720a and a preliminary eleventh barrier pattern 710a covering a lower surface of the preliminary seventh metal pattern 720a, which may collectively form a preliminary first upper wiring 730a. In example embodiments, the preliminary first upper wiring 730a may have a shape of a plate.

The third metal layer 670 and the sixth barrier layer 660 on the third region III of the substrate 100 adjacent to the first and second regions I and II of the substrate 100 in the first direction D1 may be, respectively, transformed into a tenth metal pattern 725 and a fourteenth barrier pattern 715 covering a lower surface of the tenth metal pattern 725, which may collectively form a second upper wiring 735. The third metal layer 670 and the sixth barrier layer 660 within the tenth opening may be, respectively, transformed into an eighth metal pattern and a twelfth barrier pattern covering a lower surface of the eighth metal pattern, which may collectively form a first upper contact plug.

The third metal layer 670 and the sixth barrier layer 660 on the third region III of the substrate 100 adjacent to the first and second regions I and II of the substrate 100 in the second direction D2 may be, respectively, transformed into an eleventh metal pattern 727 and a fifteenth barrier pattern 717 covering a lower surface of the eleventh metal pattern 727, which may collectively form a third upper wiring 737. The third metal layer 670 and the sixth barrier layer 660 within the eleventh opening 650 may be, respectively, transformed into a ninth metal pattern 697 and a thirteenth barrier pattern 687 covering a lower surface of the ninth metal pattern 697, which may collectively form a second upper contact plug 707.

In example embodiments, the preliminary first upper wiring 730a may be formed to overlap the first lower wiring 600 in the vertical direction. The second upper wiring 735 may be formed to overlap the second lower wiring 605 in the vertical direction, and may be electrically connected to the second lower wiring 605 through the first upper contact plug. The third upper wiring 737 may be formed to overlap the third lower wiring 607 in the vertical direction, and may be electrically connected to the third lower wiring 607 through the second upper contact plug 707.

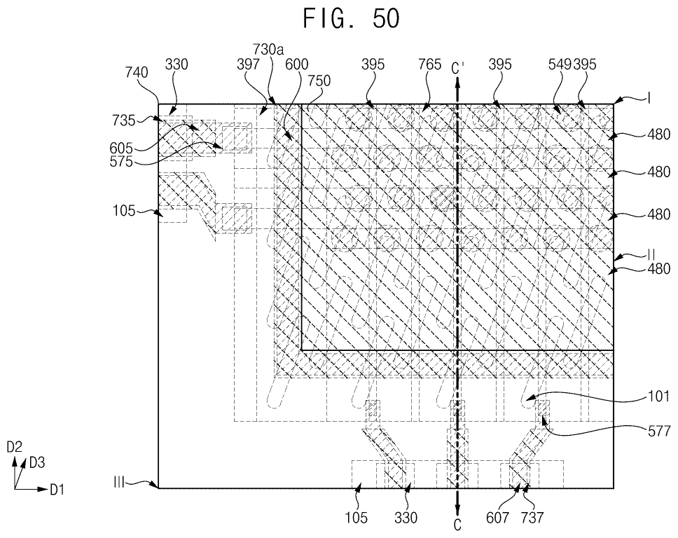

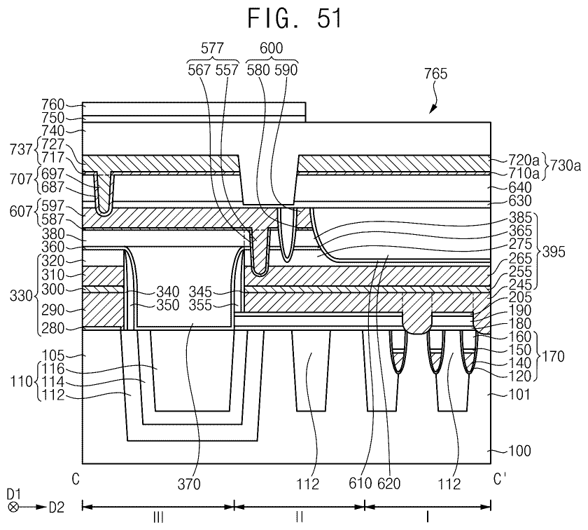

Referring to FIGS. 50 and 51, a second mold layer 740, an anti-reflection layer 750 and the photoresist pattern 760 may be sequentially formed on the preliminary first upper wiring 730a, the second and third upper wirings 735 and 737, and a bottom and a sidewall of the twelfth opening 677. The photoresist pattern 760 may be formed to include the thirteenth opening 765.

In example embodiments, the thirteenth opening 765 may be formed to overlap in the vertical direction a portion of the preliminary first upper wiring 730a excluding a portion of the preliminary first upper wiring 730a that overlaps in the vertical direction the first lower wiring 600.

In example embodiments, the second mold layer 740 may include, e.g., Spin-On-Hardmask (SOH). The anti-reflection layer 750 may include, e.g., silicon oxynitride (SiON). The photoresist pattern 760 may include, e.g., a photoresist material whose properties change in response to light.

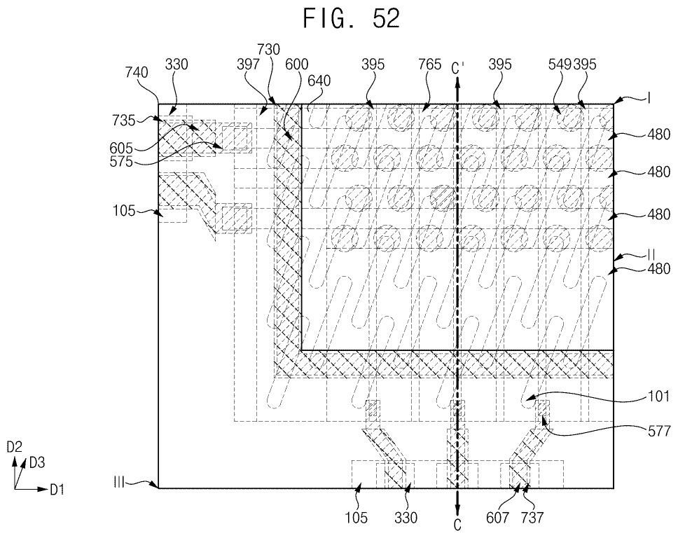

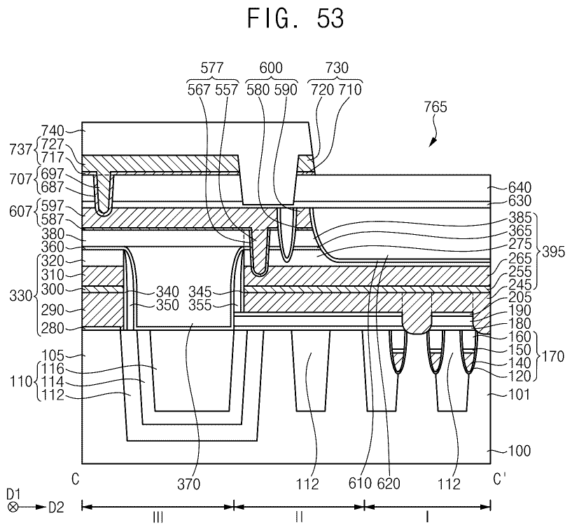

Referring to FIGS. 52 and 53, the preliminary first upper wiring 730a may be patterned by performing a second etching process using the photoresist pattern 760 as an etching mask. Accordingly, the preliminary first upper wiring 730a may be transformed into a first upper wiring 730 including a seventh metal pattern 720 and an eleventh barrier pattern 710 covering a lower surface of the seventh metal pattern 720. The second etch stop layer 630 may serve as an etch stop layer during the second etching process.

By the second etching process, the first upper wiring 730 may be formed to overlap the first lower wiring 600 in the vertical direction. Accordingly, the first upper wiring 730 may have a shape of a ring in a plan view, corresponding the first upper wiring 730. Specifically, the first upper wiring 730 may include a third extension portion extending in the second direction D2 on the portion of the second region II of the substrate 100 adjacent to the first region I of the substrate 100 in the first direction D1, and a fourth extension portion extending in the first direction D1 on the portion of the second region II of the substrate 100 adjacent to the first region I of the substrate 100 in the second direction D2. Accordingly, in a plan view, the first upper wiring 730 may have a shape of a square ring comprising two third extension portions facing each other in the first direction D1 and two fourth extension portions facing each other in the second direction D2. The third and fourth extension portions of the first upper wiring 730 may be formed to overlap the first and second extension portions of the first lower wiring 600, respectively.

The photoresist pattern 760 and the anti-reflection layer 750 may be removed by the second etching process. Accordingly, a portion of the second mold layer 740 and a portion of the first mold layer 640 may be exposed.

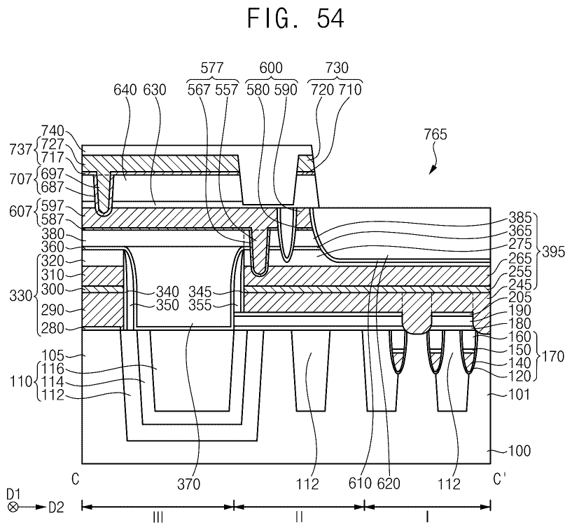

Referring to FIG. 54, as the second etching process progresses, the exposed portion of the first mold layer 640 and a portion of the second etch stop layer 630 below the exposed portion of the first mold layer 640 may be removed, and the thirteenth opening. 765 may be enlarged in the vertical direction. Accordingly, upper surfaces of the second lower contact plug 549 and the sixth and seventh insulation layers 610 and 620 on the first region I of the substrate 100 may be exposed by the enlarged thirteenth opening 765.

In example embodiments, the second etching process for the preliminary first upper wiring 730a, the first mold layer 640 and the second etch stop layer 630 may be performed in-situ.

The first mold layer 640 may remain below the first upper wiring 730. Hereinafter, for convenience of explanation, the first upper wiring 730 and the first mold layer 640 remaining below the first upper wiring 730 may be collectively referred to as a first upper wiring structure.

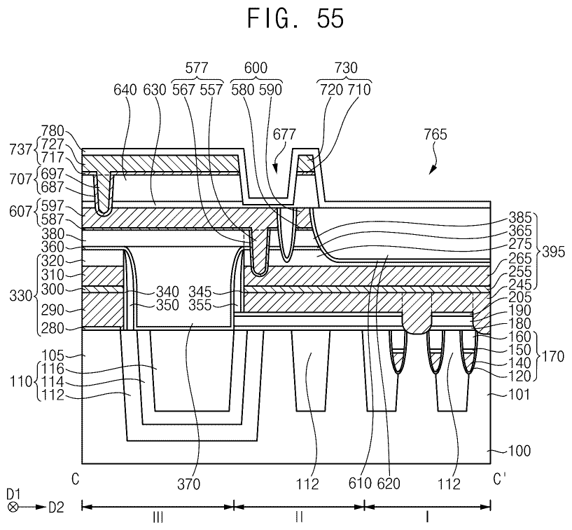

Referring to FIG. 55, the second mold layer 740 may be removed. Accordingly, the twelfth opening 677 may be formed again between the first upper wiring 730 and the second upper wiring 735 and between the first upper wiring 730 and the third upper wiring 737. Surfaces of the second and third upper wirings 735 and 737, the first mold layer 640 and the second etch stop layer 630 may be exposed.

A third etch stop layer 780 may be formed on the second and third upper wirings 735 and 737, the first mold layer 640 and the second etch stop layer 630 exposed by the twelfth opening 677, and the upper surface of the second lower contact plug 549 and the sixth and seventh insulation layers 610 and 620 exposed by the thirteenth opening 765. The third etch stop layer 780 may include, e.g., an insulating nitride such as silicon boron nitride (SiBN), etc. The second and third etch stop layers 630 and 780 may collectively form an etch stop layer structure.

Immediately after performing the second etching process, the second etch stop layer 630 may remain on a bottom of the twelfth opening 677 on the second and third regions II and III of the substrate 100. However, the second etch stop layer 630 may not remain on a bottom of the thirteenth opening 765 on the first region I of the substrate 100. Accordingly, a first thickness in the vertical direction of the etch stop layer structure on the bottom of the twelfth opening 677 on the second and third regions II and III of the substrate 100 may be greater than a second thickness in the vertical direction of the etch stop layer structure on the bottom of the thirteenth opening 765 on the first region I of the substrate 100.

In example embodiments, the second etch stop layer 630 may be a single layer, but the concept of the present invention is not limited thereto. Alternatively, for example, the second etch stop layer 630 may be multilayer, and in contrast, the third etch stop layer 780 may be a single layer. Accordingly, a first portion of the etch stop layer structure on the bottom of the thirteenth opening 765 on the first region I of the substrate 100 may be a single layer, and a second portion of the etch stop layer structure on the bottom of the twelfth opening 677 on the first and second regions II and III of the substrate 100 may be multilayer.

In example embodiments, the second thickness of the etch stop layer structure on the first region I of the substrate 100 may be approximately 80 Å to approximately 120 Å, and, preferably, may be approximately 100 Å.

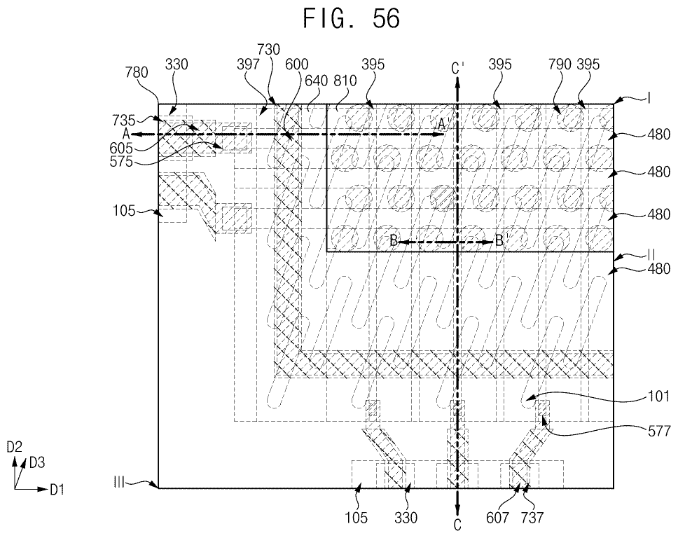

Referring to FIGS. 56 to 59, a third mold layer may be formed on the third etch stop layer 780, and the third etch stop layer 780 and the third mold layer may be partially etched to form a fourteenth opening that may partially expose the upper surface of the second lower contact plug 549.

A lower electrode layer may be formed on the exposed upper surface of the second lower contact plug 549 and the third mold layer to fill the fourteenth opening, and the lower electrode layer may be planarized until an upper surface of the third mold layer is exposed to form a lower electrode 790. The third mold layer may be removed by, e.g., a wet etching process, and accordingly, the lower electrode 790 may be formed to have a pillar shape. Alternatively, the lower electrode 790 may be formed to have a cylindrical shape. The lower electrode may include, e.g., a metal, a metal nitride, a metal silicide, doped polysilicon, etc.

A dielectric layer 800 may be formed on a surface of the lower electrode 790 and an upper surface of the third etch stop layer 780, and an upper electrode 810 may be formed on the dielectric layer 800 to form a capacitor 820 including the lower electrode 790, the dielectric layer 800 and the upper electrode 810 on the first region I of the substrate 100. The dielectric layer 800 and the upper electrode 810 on the second and third regions I and II of the substrate 100 may be removed.

The dielectric layer 800 may include, e.g., a metal oxide, and the upper electrode 810 may include, e.g., a metal, a metal nitride, a metal silicide, doped polysilicon, etc.

In example embodiments, the capacitor 820 may at least partially overlap the first to third upper wirings 730, 735 and 737 in the horizontal direction.

In the method of manufacturing a semiconductor device, the first etching process may be performed to form the preliminary first upper wiring 730a and the second and third upper wirings 735 and 737, and the second etching process may be performed on the preliminary first upper wiring 730a to form the first upper wiring 730. In this way, compared to the case where the first to third upper wirings 730, 735 and 737 are formed by a single etching process, the difficulty of the etching process may be reduced.

Additionally, during the second etching process, the second etch stop layer 630, which serves as an etch stop layer for the first and second etching processes, may be removed. Thus, overall process steps may not increase.

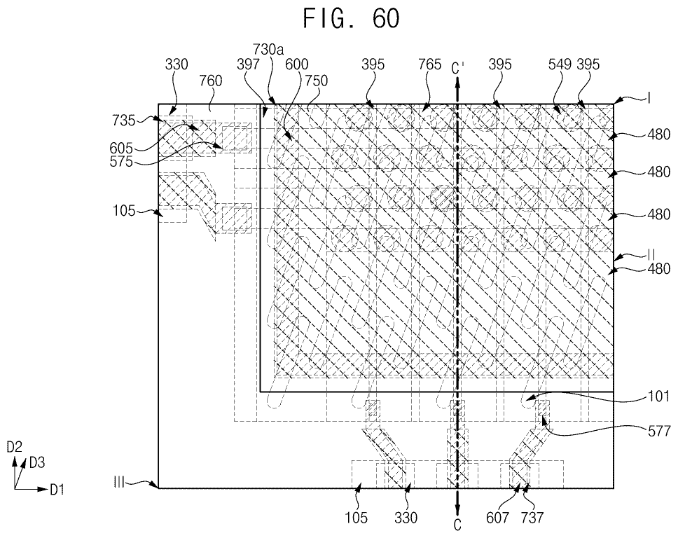

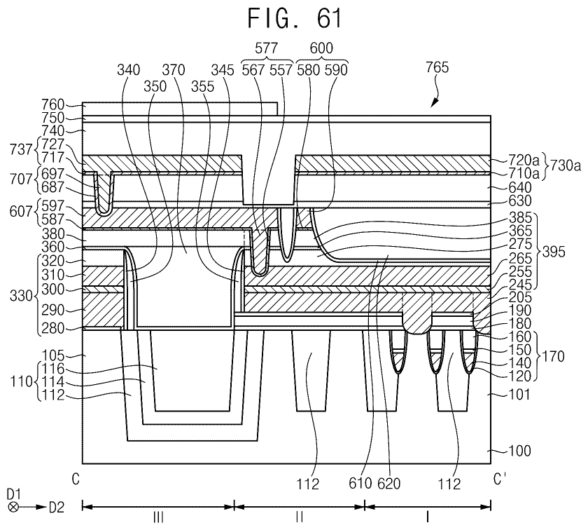

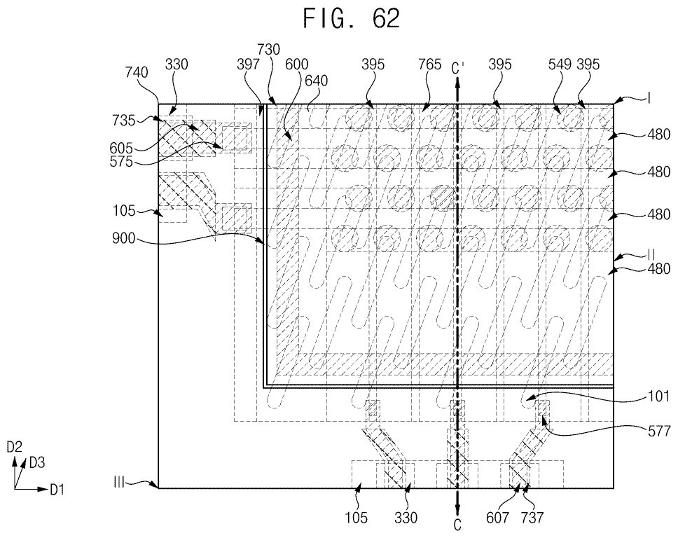

FIGS. 60 to 64 are plan views and cross-sectional views illustrating a method of manufacturing a semiconductor device according to example embodiments. Specifically, FIGS. 60 and 62 are the plan views, and FIGS. 61 and 63 to 64 are cross-sectional views taken along lines C-C′ of corresponding plan views, respectively. This method of manufacturing a semiconductor device may include processes substantially the same as or similar to those illustrated with reference to FIGS. 1 to 59, and thus repeated explanations thereof are omitted herein.

Referring to FIGS. 60 and 61, processes that are substantially the same as or similar to those illustrated with reference to FIGS. 1 to 51 may be performed. However, unlike the processes illustrated with reference to FIGS. 50 and 51, the thirteenth opening 765 may also overlap in the vertical direction the portion of the preliminary first upper wiring 730a that overlaps the first lower wiring 600 in the vertical direction. For example, the thirteenth opening 765 may be formed to overlap the preliminary first upper wiring 730a in the vertical direction as a whole.

In example embodiments, the thirteenth opening 765 may at least partially overlap in the vertical direction a portion of the second insulating interlayer adjacent to the first lower wiring 600 on the second region II of the substrate 100.

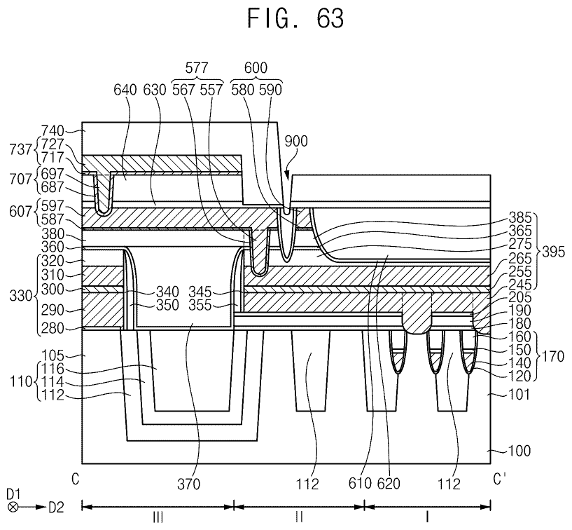

Referring to FIGS. 62 and 63, processes that are substantially the same as or similar to those illustrated with reference to FIGS. 52 to 53 may be performed. However, unlike processes illustrated with reference to FIGS. 52 and 53, the preliminary first upper wiring 730a may be completely removed, and thus, the first upper wiring structure including the first upper wiring 730 and the first mold layer remaining below the first upper wiring 730 may not be formed.

The preliminary first upper wiring 730a may include, e.g., a metal or a metal nitride, and thus, the etching rate of the preliminary first upper wiring 730a may be relatively slower than that of the first mold layer 640 including, e.g., TEOS. Accordingly, during the etching process of the preliminary first upper wiring 730a, a portion of the first mold layer 640 that does not overlap the photoresist pattern 760 and the preliminary first upper wiring 730a in the vertical direction may be removed relatively quickly. Thus, an upper portion of the second insulating interlayer that overlaps the thirteenth opening 765 in the vertical direction may be exposed to be partially etched. Accordingly, a second recess structure 900 may be formed on the upper portion of the second insulating interlayer adjacent to the first lower wiring 600.

In example embodiments, the second recess structure 900 may be formed to have a shape of a ring in a plan view. Specifically, the second recess structure 900 may include a fifth recess extending in the second direction D2 through the upper portion of the second insulating interlayer between the first and second lower wirings 600 and 605 on the second region II of the substrate 100 adjacent to the first region I of the substrate in the first direction D1, and a sixth recess extending in the first direction D1 through the upper portion of the second insulating interlayer between the first and third lower wirings 600 and 607 on the second region

II of the substrate adjacent to the first region I of the substrate in the second direction D2. Accordingly, in a plan view, the second recess structure 900 may be formed to have a shape of a square ring comprising two fifth recesses facing each other in the first direction D1 and two sixth recesses facing each other in the second direction D2.

A bottom of the second recess structure 900 may be formed at the same height as a bottom of the first lower wiring 600, but the concept of the present invention is not limited thereto. For example, the bottom of the second recess structure 900 may be formed to be higher or lower than a bottom of the first lower wiring 600.

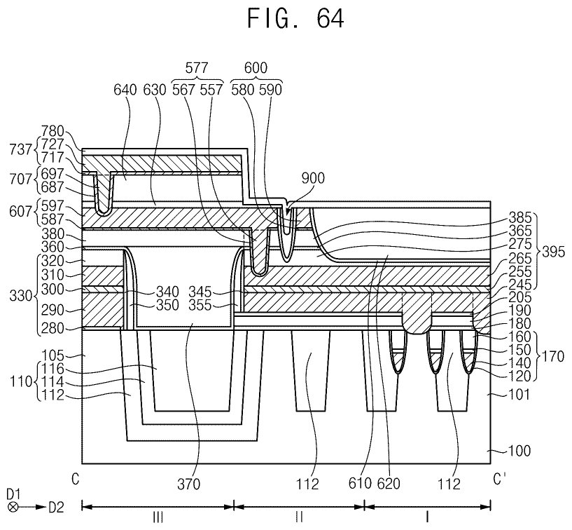

Referring to FIG. 64, processes that are substantially the same as or similar to those illustrated with reference to FIGS. 54 and 55 may be performed. However, unlike the processes illustrated with reference to FIG. 55, the third etch stop layer 780 may be formed on the second and third upper wirings 735 and 737, the first mold layer 640, the second etch stop layer 630, the second insulating interlayer including the second recess structure 900 and the first lower wiring 600.

Thereafter, manufacturing of the semiconductor device may be completed by performing processes substantially the same as or similar to the processes illustrated with reference to FIGS. 56 to 59.

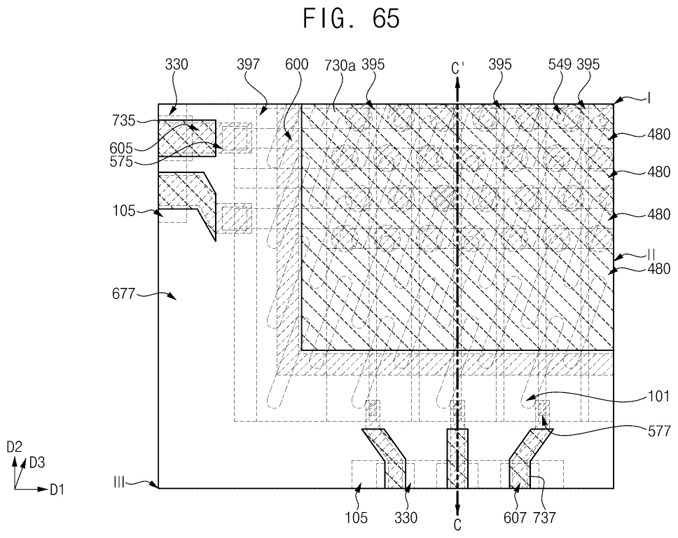

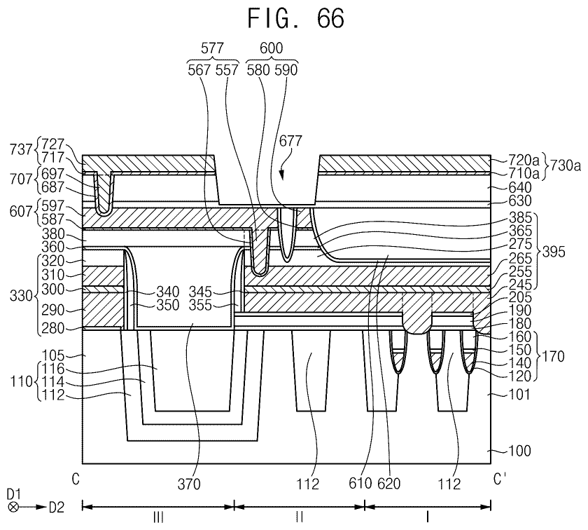

FIGS. 65 to 71 are plan views and cross-sectional views illustrating a method of manufacturing a semiconductor device according to example embodiments. Specifically, FIGS. 65, 67 and 69 are the plan views, and FIGS. 66, 68 and 70-71 are cross-sectional views taken along lines C-C′ of corresponding plan views, respectively. This method may include processes substantially the same as or similar to those illustrated with reference to FIGS. 1 to 59, and thus repeated explanations thereof are omitted herein.

Referring to FIGS. 65 and 66, processes that are substantially the same as or similar to those illustrated with reference to FIGS. 1 to 49 may be performed. However, unlike the processes illustrated with reference to FIGS. 48 and 49, the preliminary first upper wiring 730a may be formed so as not to overlap the first lower wiring 600 in the vertical direction.

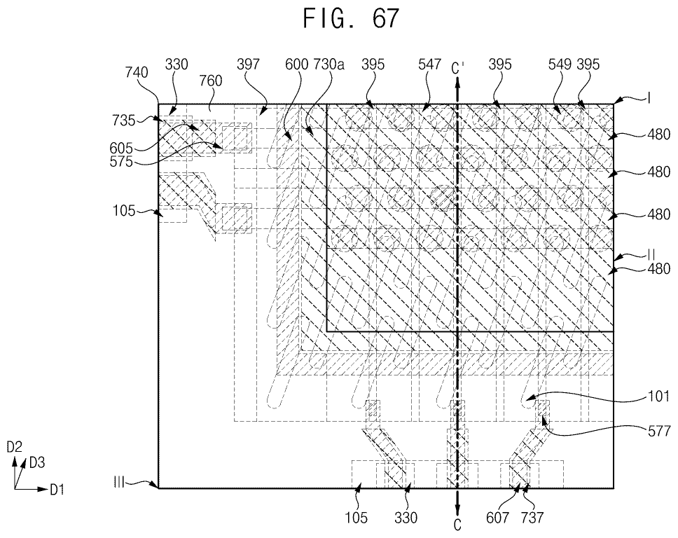

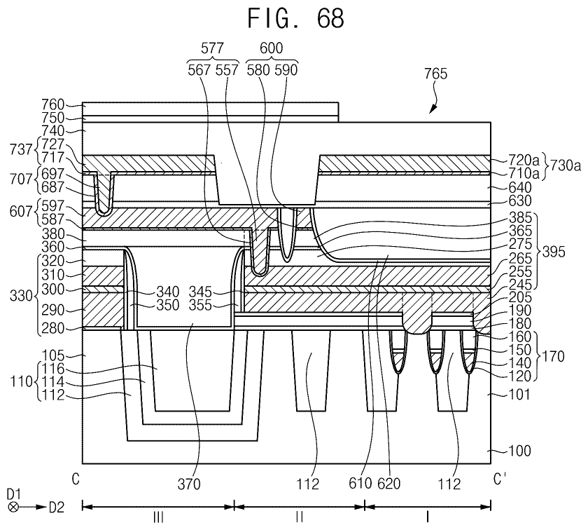

Referring to FIGS. 67 and 68, processes that are substantially the same as or similar to those illustrated with reference to FIGS. 50 and 51 may be performed. However, unlike the processes illustrated with reference to FIGS. 50 and 51, the thirteenth opening 765 may be formed to overlap in the vertical direction a portion of the preliminary first upper wiring 730a excluding a portion of the preliminary first upper wiring 730a adjacent to the first lower wiring 600. For example, the thirteenth opening 765 may be formed to overlap a central portion of the preliminary first upper wiring 730a in the vertical direction, excluding an edge portion of the preliminary first upper wiring 730a in the first and second directions D1 and D2.

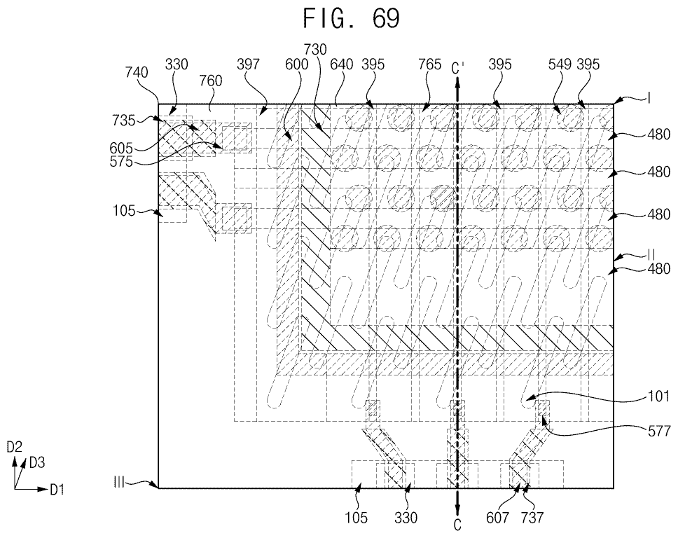

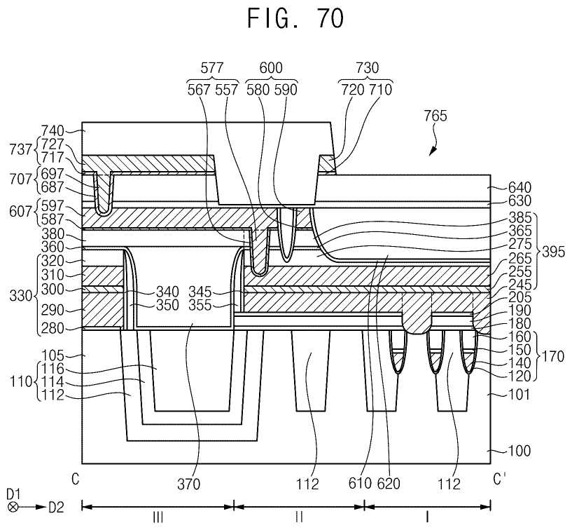

Referring to FIGS. 69 and 70, processes that are substantially the same as or similar to those illustrated with reference to FIGS. 52 and 53 may be performed. However, unlike the processes illustrated with reference to FIGS. 52 and 53, the first upper wiring 730 may be formed so as not to overlap the first lower wiring 600 in the vertical direction.

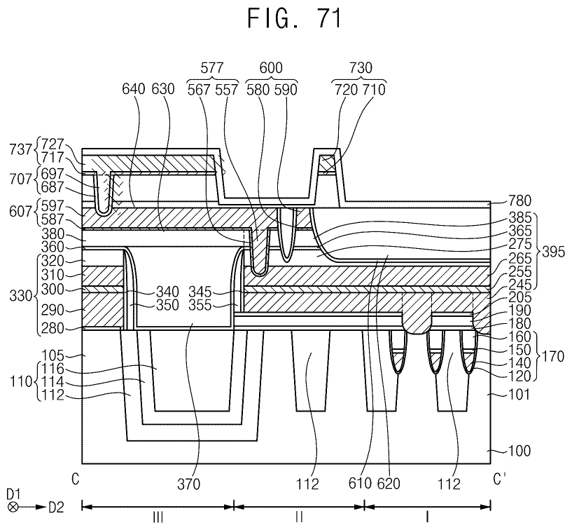

Referring to FIG. 71, manufacturing of the semiconductor device may be completed by performing processes substantially the same as or similar to the processes illustrated with reference to FIGS. 54 to 59.

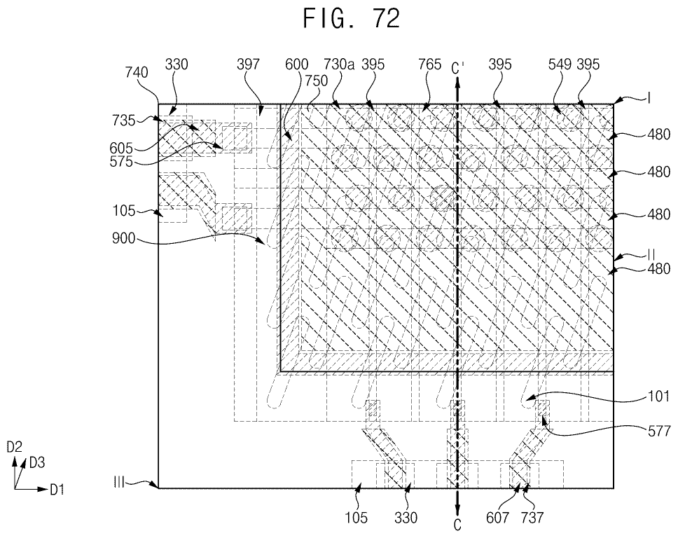

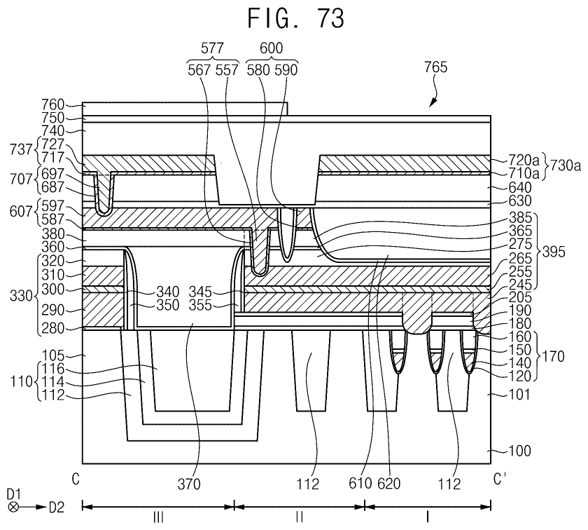

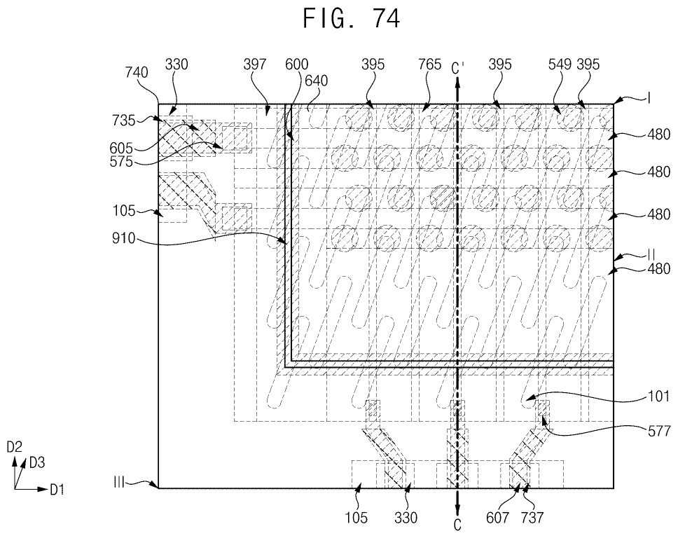

FIGS. 74 to 76 are plan views and cross-sectional views illustrating a method of manufacturing a semiconductor device according to example embodiments. Specifically, FIGS. 72 and 74 are the plan views, and FIGS. 73 and 75-76 are cross-sectional views taken along lines C-C′ of corresponding plan views, respectively. This method of manufacturing a semiconductor device may include processes substantially the same as or similar to those illustrated with reference to FIGS. 1 to 59, and thus repeated explanations thereof are omitted herein.

Referring to FIGS. 72 and 73, processes that are substantially the same as or similar to those illustrated with reference to FIGS. 1 to 49 may be performed. However, unlike the processes illustrated with reference to FIGS. 48 and 49, the preliminary first upper wiring 730a may be formed to not overlap the first lower wiring 600 in the vertical direction.

Thereafter, processes that are substantially the same as or similar to those illustrated with reference to FIGS. 50 and 51 may be performed. However, unlike the processes illustrated with reference to FIGS. 50 and 51, the thirteenth opening 765 may be formed to overlap the preliminary first upper wiring 730a in the vertical direction as a whole.

In example embodiments, the thirteenth opening 765 may be formed to at least partially overlap the first lower wiring 600 in the vertical direction.

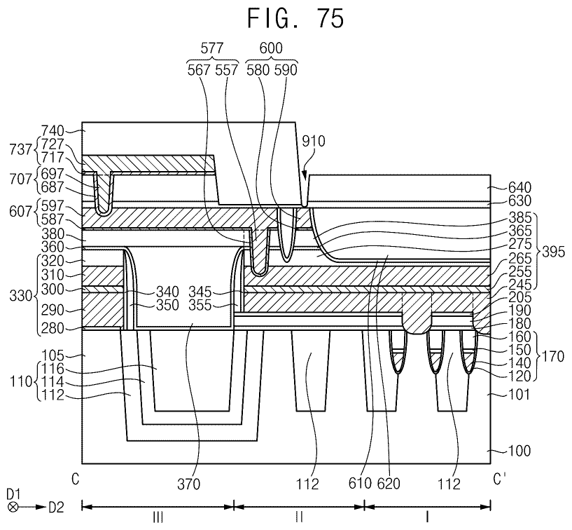

Referring to FIGS. 74 and 75, processes that are substantially the same as or similar to those illustrated with reference to FIGS. 52 and 53 may be performed. However, unlike the processes illustrated with reference to FIGS. 52 and 53, the preliminary first upper wiring 730a may be completely removed. Thus, the first upper wiring structure including the first upper wiring 730 and the first mold layer 640 remaining below the first upper wiring 730 may not be formed.

The preliminary first upper wiring 730a may include, e.g., a metal or a metal nitride, and thus, the etching rate of the preliminary first upper wiring 730a may be relatively slower than that of the first mold layer 640 including, e.g., TEOS. Accordingly, during the etching process of the preliminary first upper wiring 730a, a portion of the first mold layer 640 that does not overlap the photoresist pattern 760 and the preliminary first upper wiring 730a in the vertical direction may be removed relatively quickly. Thus, a portion of the second etch stop layer 630 that overlaps the thirteenth opening 765 in the vertical direction may be exposed.

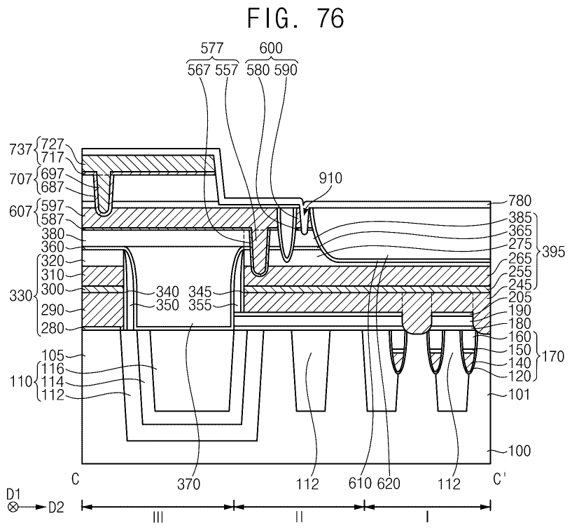

Referring to FIG. 76, processes that are substantially the same as or similar to those illustrated with reference to FIGS. 54 and 55 may be performed.

However, unlike the processes illustrated with reference to FIG. 54, the first lower wiring 600 below the portion of the second etch stop layer 630 that overlaps the thirteenth opening 765 in the vertical direction may be exposed. Furthermore, an upper portion of the exposed portion of the first lower wiring 600 may be etched to form a third recess structure 910. In example embodiments, the third recess structure 910 may be formed to have a shape

of a ring in a plan view. Specifically, the third recess structure 910 may include a seventh recess extending in the second direction D2 through the first lower wiring 600, and an eighth recess extending in the first direction D1 through the first lower wiring 600. Accordingly, in a plan view, the third recess structure 910 may be formed to have a shape of a square ring comprising two seventh recesses facing each other in the first direction D1 and two eighth recesses facing each other in the second direction D2.

The third recess structure 910 may completely penetrate the first lower wiring 600, and a bottom thereof may be formed to be lower than a bottom of the first lower wiring 600. However, the concept of the present invention is not limited thereto, and the bottom of the third recess structure 910 may be formed to be higher than the bottom of the first lower wiring 600, so that the third recess structure 910 may be formed to only partially penetrate an upper portion of the first lower wiring 600.

Manufacturing of the semiconductor device may be completed by performing processes substantially the same as or similar to the processes illustrated with reference to FIGS. 56 to 59.

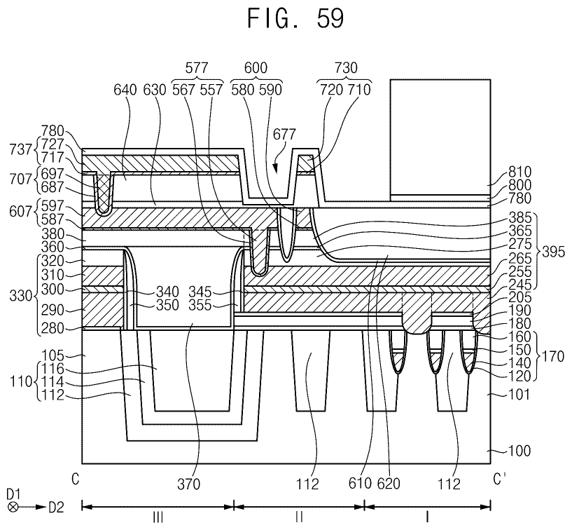

In the method of manufacturing the semiconductor device, when formed to include the first upper wiring 730 illustrated in FIGS. 59 and 71, the second recess structure 900 of FIG. 64 or the third recess structure 910 of FIG. 76 may not be formed. Accordingly, it is possible to prevent the sixth conductive pattern 265 of the bit line structure 395 from being damaged due to the second and third recess structures 900 and 910 formed during the second etching process.

Alternatively, the first upper wiring 730 illustrated in FIGS. 59 and 71 may be removed, and thus the second and third recess structures 900 and 910 of FIGS. 64 and 76 may be formed. In this case, a bridging problem between the first to third upper wirings 730, 735 and 737 may be improved or eliminated, and the integration degree of the semiconductor device may be improved.

Accordingly, the manufacturing method of the semiconductor device may be appropriately selected by considering the problem of damage to the bit line structure 395 and the bridging problem between the first to third upper wirings 730, 735, and 737.

While the present inventive concepts have been shown and described with reference to example embodiments thereof, it will be understood by those of ordinary skill in the art that various changes in form and details may be made thereto without departing from the spirit and scope of the present invention as set forth by the following claims.

What is claimed is:

1. A semiconductor device comprising:
an active pattern on a substrate including a cell array region and an extension region;
a gate structure on the active pattern, the gate structure extending in a first direction parallel to an upper surface of the substrate;
a bit line structure on the active pattern, the bit line structure extending in a second direction parallel to the upper surface of the substrate and crossing the first direction;
a lower contact plug structure on the cell array region of the substrate, the lower contact plug structure on an end portion of the active pattern;
a first lower wiring extending on the extension region along a boundary of the cell array region and the extension region, the first lower wiring at least partially overlapping the lower contact plug structure in a horizontal direction parallel to the upper surface of the substrate;
an upper wiring extending on the extension region along the boundary of the cell array region and the extension region, the upper wiring on the first lower wiring; and
a capacitor on the lower contact plug structure.

2. The semiconductor device of claim 1, wherein the first lower wiring and the upper wiring overlap in a vertical direction parallel to the upper surface of the substrate.

3. The semiconductor device of claim 1, wherein the first lower wiring and the upper wiring do not overlap in a vertical direction parallel to the upper surface of the substrate.

4. The semiconductor device of claim 1, wherein the extension region surrounds the cell array region, and each of the first lower wiring and the upper wiring has a shape of a ring in a plan view.

5. The semiconductor device of claim 4, wherein each of the first lower wiring and the upper wiring has a shape of a square ring in a plan view.

6. The semiconductor device of claim 1, further comprising:
a second lower wiring on the extension region of the substrate, the second lower wiring electrically connected to the gate structure or the bit line structure; and
an etch stop layer structure on the lower contact plug structure and the first lower wiring and second lower wiring.

7. The semiconductor device of claim 6, wherein a first portion of the etch stop layer structure on the cell array region is a single layer, and a second portion of the etch stop layer structure on the extension region is at least partially a multilayer.

8. The semiconductor device of claim 1, wherein the upper wiring at least partially overlaps the capacitor in the horizontal direction.

9. A semiconductor device comprising:
an active pattern on a substrate including a cell array region and an extension region;
a gate structure on the active pattern, the gate structure extending in a first direction parallel to an upper surface of the substrate;
a bit line structure on the active pattern, the bit line structure extending in a second direction parallel to the upper surface of the substrate and crossing the first direction;
a lower contact plug structure on the cell array region of the substrate, the lower contact plug structure on an end portion of the active pattern;
a lower wiring extending on the extension region along a boundary of the cell array region and the extension region and including a recess formed at an upper portion thereof, the recess extending on the extension region along the boundary of the cell array region and the extension region; and
a capacitor on the lower contact plug structure.

10. The semiconductor device of claim 9, wherein a bottom of the recess is higher than a bottom of the lower wiring.

11. The semiconductor device of claim 9, wherein a bottom of the recess is lower than a bottom of the lower wiring.

12. The semiconductor device of claim 9, wherein the extension region surrounds the cell array region, and each of the lower wiring and the recess has a shape of a ring in a plan view.

13. The semiconductor device of claim 12, wherein each of the lower wiring and the recess has a shape of a square ring in a plan view.

14. The semiconductor device of claim 9, wherein the lower wiring and the lower contact plug structure overlap in a horizontal direction parallel to the upper surface of the substrate.

15. A semiconductor device comprising:
an active pattern on a substrate including a cell array region and an extension region;
a gate structure on the active pattern, the gate structure extending in a first direction substantially parallel to an upper surface of the substrate;
a bit line structure on the active pattern, the bit line structure extending in a second direction substantially parallel to the upper surface of the substrate and crossing the first direction;
a lower contact plug structure on the cell array region of the substrate, the lower contact plug structure on an end portion of the active pattern;
a lower wiring extending on the extension region along a boundary of the cell array region and the extension region;
an insulating interlayer covering a sidewall of the lower contact plug structure and a sidewall of the lower wiring and including a recess formed at an upper portion thereof, the recess extending on the extension region along the boundary of the cell array region and the extension region; and
a capacitor on the lower contact plug structure.

16. The semiconductor device of claim 15, wherein a bottom of the recess is higher than a bottom of the lower wiring.

17. The semiconductor device of claim 15, wherein a bottom of the recess is lower than a bottom of the lower wiring.

18. The semiconductor device of claim 15, wherein the extension region surrounds the cell array region, and each of the lower wiring and the recess has a shape of a ring in a plan view.

19. The semiconductor device of claim 18, wherein each of the lower wiring and the recess has a shape of a square ring in a plan view.

20. The semiconductor device of claim 15, wherein the lower wiring and the lower contact plug structure overlaps in a horizontal direction substantially parallel to the upper surface of the substrate.
